(19) United States
(12) Patent Application Publication
(10) Pub. No.: US 2010/0148313 A1
(43) Pub. Date: Jun. 17, 2010

(54) SEMICONDUCTOR APPARATUS AND METHOD OF MANUFACTURING THE SAME

(75) Inventor: Yoshiaki KOMURO, Kanagawa (JP)

Correspondence Address: ROBERT J. DEPKE;LEWIS T. STEADMAN, ROCKEY, DEPKE & LYONS, LLC, SUITE 5450 SEARS TOWER, CHICAGO, IL, 60606-6306, US

(73) Assignee: SONY CORPORATION, Tokyo (JP)

(21) Appl. No.: 12/628,703

(22) Filed: Dec. 1, 2009

(30) Foreign Application Priority Data
Dec. 11, 2008 (JP) 2008-315468

(51) Int. Cl. H01L 23/544; H01L 21/78

(52) U.S. Cl. 257/620; 438/462; 257/E23.179; 257/E21.599

(57) ABSTRACT

Disclosed herein is a semiconductor apparatus, wherein a technique for manufacturing one semiconductor region by dividing the one semiconductor region into a plurality of divisional regions in regard of a step is applied, and one-side device portions formed simultaneously by a one-side treatment conducted primarily for the divisional region on one side and other-side device portions formed simultaneously by an other-side treatment conducted primarily for the divisional region on the other side are mixedly present in a joint region joining a boundary between the divisional regions.

The present application claims priority to Japanese Patent Application JP 2008-315468 filed in the Japan Patent Office on Dec. 11, 2008, the entire content of which is hereby incorporated by reference.

### BACKGROUND OF THE INVENTION

1. Field of the Invention

The present invention relates to a semiconductor apparatus, such as a solid-state image sensing apparatus, and a method of manufacturing the same. More particularly, the invention relates to a mechanism of manufacturing a semiconductor apparatus by once dividing it into a plurality of regions.

2. Description of the Related Art

In the case where fine devices should be formed over a large area, a mechanism is considered in which a region too large in size to be formed by a one-shot process is divided into a plurality of divisional regions, the divisional regions are individually processed, and thereafter the divisional regions thus processed are joined to each other so as to form a larger-sized processed region (this mechanism will be referred to as the region dividing and joining method). For instance, Japanese Patent Laid-Open No. 2005-223707 (hereinafter referred to as Patent Document 1) proposes the use of a technology called divisional exposure in the case of forming a large-area solid-state image sensing apparatus.

### SUMMARY OF THE INVENTION

When divisional exposure is performed for manufacturing a large-sized semiconductor apparatus, however, the alignment error (offset) on the left side of the boundary of exposure is different from that on the right side of the boundary. As a result, a difference in characteristics is generated between the left side and the right side of the boundary of exposure. If the difference of characteristics varies gradually, it does not produce any serious problem. In the case of performing exposure individually on the left side and on the right side, however, the boundary of exposure is generated along a straight line, producing a clear difference in characteristics. Consequently, a step (difference in level) in characteristics appears conspicuously between the left side and the right side of the boundary.

For example, in the case of a solid-state image sensing apparatus, the generation of the boundary on a straight line causes a distinct difference in characteristics. As a result, the step in output appearing between the left side and the right side of the boundary line is observed as a bright line or a black line, so that the boundary is conspicuously seen.

Thus, there is a need for a mechanism by which the influence of the step(s) generated in characteristics upon application of the region dividing and joining method can be alleviated.

According to an embodiment of the present invention, there is provided a semiconductor apparatus, wherein a technique for manufacturing one semiconductor region by dividing the one semiconductor region into a plurality of divisional regions in regard of a step is applied, and one-side device portions formed simultaneously by a one-side treatment conducted primarily for the divisional region on one side and other-side device portions formed simultaneously by an other-side treatment conducted primarily for the divisional region on the other side are mixedly present in a joint region joining a boundary between the divisional regions.

According to an embodiment of the present invention, the region dividing and joining method for manufacturing one semiconductor region by dividing the semiconductor region into a plurality of divisional regions in regard of a working step is applied, wherein, first, in a one-side treatment conducted primarily for the divisional region on one side, one-side device portions are formed in the one-side divisional region and, simultaneously, at least part of one-side device portions are formed also in a joint region in the vicinity of a boundary between the divisional regions. Further, in an other-side treatment conducted primarily for the divisional region on the other side, at least part of other-side device portions are formed also in spaces between the one-side device portions in the joint region.

Specifically, the device portions formed simultaneously by the one-side treatment (exposure and ion implantation conducted primarily for the divisional region on one side) and the device portions formed simultaneously by the other-side treatment (exposure and ion implantation conducted primarily for the divisional region on the other side) are made mixedly present in the joint region through which the divisional regions are connected to each other in the vicinity of the boundary.

Upon generation of an offset, offset states based respectively on the treatments relevant to the divisional regions are mixedly present in the joint region near the boundary. On the basis of characteristics, differences in characteristics according to the respective offsets are generated. Since the offsets are mixedly present in the joint region near the boundary, the offsets are averaged on the whole in the joint region.

According to an embodiment of the present invention, the exposure or ion implantation areas by the treatment conducted primarily for a one-side divisional region and the exposure or ion implantation areas by the treatment conducted primarily for an other-side divisional region are mixedly present in the joint region in the vicinity of the boundary between the divisional regions. Therefore, the phenomenon in which a difference in characteristics between the divisional regions is conspicuously observed is moderated. In other words, the difference of characteristics in the joint region becomes more difficult to visually recognize. When this is applied to a solid-state image sensing apparatus, the difference of characteristics in the joint region (or at the boundary), as well as the bright line or black line arising therefrom, can be made inconspicuous.

### BRIEF DESCRIPTION OF THE DRAWINGS

FIG. 1 shows diagrams for illustrating a manufacturing method according to a comparative example given in comparison to embodiments of the present invention (hereinafter referred to as the present embodiment);

FIG. 2 shows diagrams for illustrating the problems involved in the manufacturing method according to the comparative example;

FIG. 3 shows diagrams (Part 1) for illustrating the fundamentals of the mechanism of the present embodiment;

FIG. 4 shows diagrams (Part 2) for illustrating the fundamentals of the mechanism of the present embodiment;

FIG. 5 shows diagrams (Part 3) for illustrating the fundamentals of the mechanism of the present embodiment;

FIG. 6 shows diagrams (Part 4) for illustrating the fundamentals of the mechanism of the present embodiment;

FIGS. 7A to 7C show diagrams for illustrating a manufacturing method according to a first embodiment of the invention (the case where there is no offset);

FIG. 8 shows diagrams for illustrating the manufacturing method according to the first embodiment (the case where an offset is present);

FIG. 9 shows diagrams for illustrating a manufacturing method according to a second embodiment of the invention;

FIG. 10 is a general view of a solid-state image sensing apparatus;

FIG. 11 shows diagrams for illustrating a comparative example given in comparison to a first application example;

FIG. 12 shows diagrams for illustrating the first application example;

FIG. 13 shows a diagram for illustrating a second application example;

FIG. 14 shows diagrams for illustrating a third application example;

FIG. 15 shows diagrams for illustrating a fourth application example; and

FIG. 16 shows diagrams for illustrating a fifth application example.

### DETAILED DESCRIPTION OF THE PREFERRED EMBODIMENTS

Now, embodiments of the present invention will be described in detail below referring to the drawings.

The description will be made in the following order.

1. Comparative example and problems involved therein
2. Fundamentals of manufacturing methods according to the present embodiment
3. First embodiment (isolation region is formed by composition of two runs of exposure, gate electrode is formed by one-time exposure)
4. Second embodiment (isolation region is formed by one-time exposure)
5. Application examples

### Comparative Example and Problems Involved Therein

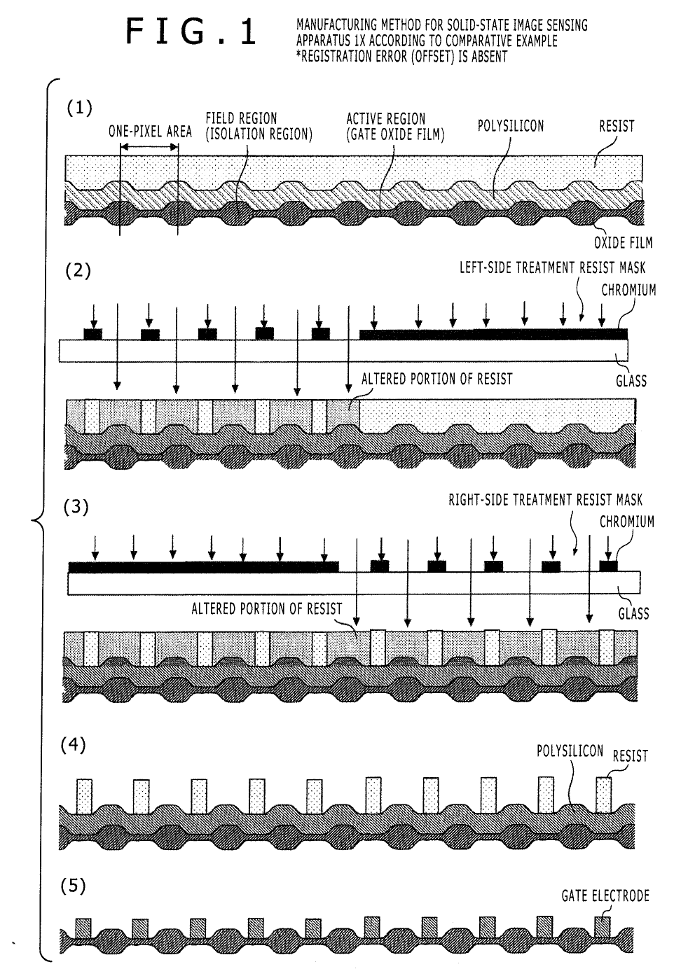

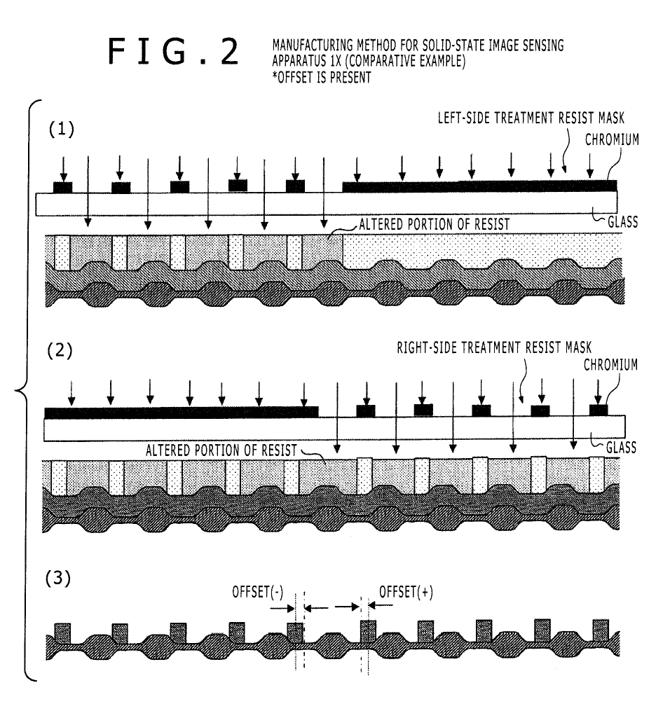

FIG. 1 shows diagrams for illustrating a manufacturing method according to a comparative example given in comparison to the present embodiment. FIG. 2 shows diagrams for illustrating the problems involved in the manufacturing method according to the comparative example.

In a camera such as a single-lens reflex camera, the magnitude of angle of view is an important factor for producing a gradation taste of the camera, and it is said that a greater magnitude is more preferable.

In related-art cameras using a silver salt film (referred to as film cameras), for instance, 35-mm films are normally used. Nowadays, in the field of image apparatuses, solid-state image sensing apparatuses of the CDD (charge coupled device) type or of the MOS (metal oxide semiconductor) or CMOS (complementary metal oxide semiconductor) type for detection of light are used. Typical examples of these are the apparatuses called digital cameras.

In the solid-state image sensing apparatuses, also, those so sized that an effective image sensing region thereof corresponds to the 35-mm films in the film cameras are demanded, but there have been few solid-state image sensing apparatuses of such a size. One of the reasons for this situation is that solid-state image sensing apparatuses of this size are expensive, and another reason is that the technology for manufacturing solid-state image sensing apparatuses of this size is very difficult to realize.

For manufacturing a solid-state image sensing apparatus, for example, processing or ion implantation or the like is carried out using as a protective film a resist printed by photolithography. As for the size adapted to photolithography, however, there is a limitation of about 26 mm×33 mm or about 23 mm×35 mm, due to restrictions regarding the printing apparatus. A solid-state image sensing apparatus requires a peripheral circuitry in addition to the effective image sensing region, so that in order to secure an effective image sensing region corresponding to the 35-mm films, an overall size of at least about 30 mm×38 mm is needed. A solid-state image sensing apparatus of such a size is difficult to manufacture by use of a photolithography apparatus according to the related art.

As a countermeasure against this problem, a mechanism is considered in which a region too large in size to be formed by a one-shot process is divided into a plurality of regions, the divisional regions are individually subjected to exposure and ion implantation or the like, and the divisionally processed regions are joined to each other so as to form a larger-sized processed region (region dividing and joining method). In the case of dividing the region to be processed into two divisional regions, for example, one solid-state image sensing apparatus is manufactured through a two-shot process in which one of the halves adjacent to each other at a boundary at the center in the longitudinal direction of the solid-state image sensing apparatus is first subjected to exposure and thereafter the remaining half is subjected to exposure.

The region dividing and joining method will be described specifically below, referring to FIG. 1. Incidentally, for simpler description, a pixel structure is assumed to be composed of one active region and one gate electrode. The active regions are partitioned from each other by an isolation region. In other words, the solid-state image sensing apparatus 1X is partitioned into active regions in which various semiconductor devices inclusive of transistors are formed, and isolation regions in which isolation films for electrically isolating the semiconductor devices from each other are formed.

Examples of the method for forming the isolation regions include a LOCOS (local oxidation) method, a PBL (poly buffered LOCOS) method, and an STI (shallow trench isolation) method. The LOCOS method is a method in which a pad oxide film and a pad nitride film are sequentially formed, a substrate is exposed in areas corresponding to the isolation regions by an etching step, and the exposed regions of the substrate are oxidized by an oxidizing step to form an isolation film there. The PBL method is a method in which a polysilicon film is intermediately provided between a pad oxide film and a pad nitride film so as to play the role of a buffer. The STI method is a method in which a pad oxide film and a pad nitride film are sequentially formed, a substrate is exposed in areas corresponding to the isolation regions by an etching step, the exposed regions of the substrate are etched to form trenches, and the trenches are filled up with an insulating material to form an isolation film there. The following description will be made referring to the case where isolation of devices is carried out by applying the LOCOS method mentioned above.

In an active region there are present an emitter region and a base region (a gate oxide film or the like) which constitute a transistor, and so on; in the drawings, the base region and layers on the upper side thereof are paid attention to. In addition, two exposure areas on both sides of a boundary located at the center of a solid-state image sensing apparatus 1X are expressed as “the left side and the right side” of exposure. Incidentally, whichever of the left side and the right side is subjected first to exposure is of no importance.

In the following, for simplification, description will be made based on a system in which exposure is conducted in the condition where a resist mask is disposed directly over a resist (proximity system). In practical photolithography steps, however, a system in which exposure is conducted by performing projection through a resist mask spaced from a resist (projection system) is often used. Incidentally, the photolithography steps will be described referring to the positive type in which an object material is removed in areas where it is irradiated with light through the mask. These points apply also in the manufacturing methods according to embodiments of the present invention which will be described later.

[Manufacturing Method According to Comparative Example]

As shown in FIG. 1(1), a gate oxide film and a LOCOS (local oxidation of silicon) oxide film are formed on a silicon wafer as underlying layer. These underlying layer patterns are also formed by two shots of exposure to be described below, but detailed description thereof is omitted for simplification of description. A layer of polysilicon to serve as a gate electrode material is formed on the underlying layer patterns by such technique as CVD (chemical vapor deposition). Further, a resist as a material for forming a resist pattern by lithography is applied to the polysilicon layer.

As shown in FIG. 1(2), either one of a left-side half and a right-side half present on respective sides of a boundary located at a midpoint in the longitudinal direction of the solid-state image sensing apparatus 1X is subjected to a first run of exposure (first-time exposure). In the drawings, the case where the left-side half is subjected to the first shot is shown. For patternwise exposure, a resist mask is placed over the resist. The resist mask has light-transmissive portions composed of a glass, and light shield portions composed of the glass and a light shield material (chromium or the like) provided thereon. In the remaining half (in the figures, the right-side half), the resist is shielded from light by the resist mask or by a structure of the system so that the resist in the right-side half is not irradiated with light at all. The resist in the portions irradiated with the light is altered to be easy to remove by a liquid chemical or the like.

In the subsequent second run of exposure, as shown in FIG. 1(3), the half not yet subjected to exposure (in the figures, the right half) is subjected to exposure. In this instance, the resist in the opposite-side portion having been subjected to the first shot (in the figures, the left half) is prevented from being irradiated with light.

Incidentally, in this example, a joint area is set at the isolation region so that in this area, part of the resist is subjected to overlap exposure, namely, part of the resist forms a double-exposure area.

Next, as shown in FIG. 1(4), the altered layer in the resist areas where it has been irradiated with light is removed by a liquid chemical in a developing step (for example, dry etching) of the lithography.

Subsequently, as shown in FIG. 1(5), dry etching is conducted using the remaining resist as a mask, whereby the other portions of the polysilicon layer than the gate electrode portions are removed. Furthermore, the resist on the polysilicon layer thus left is removed by ashing, to expose (form) the gate electrodes.

[Problems Involved in Manufacturing Method According to Comparative Example]

However, in the second run of exposure (second-time exposure), the following problems would occur. For example, where the solid-state image sensing apparatus 1X is small in size, only one shot is needed for the resist in the manufacturing process. Besides, when the semiconductor patterns in the underlying layer are subjected to exposure, the printing is conducted with an offset which is substantially constant throughout the exposure area under an ideal alignment. Where the solid-state image sensing apparatus 1X is large in size, on the other hand, two runs of exposure are applied in the manufacturing process, whereon the boundary (joint region) between the two exposure areas is located at the center of the solid-state image sensing apparatus 1X and is therefore conspicuous.

FIG. 2 illustrates a situation relevant to this problem. As shown in FIG. 2(1), the left-side half of the solid-state image sensing apparatus 1X is subjected to exposure, whereon an offset of the resist pattern relative to the underlying structure is generated. Here, a case where the resist pattern shows a leftward offset relative to the underlying structure is illustrated.

Next, as shown in FIG. 2(2), exposure of the right-side half is conducted. Here, a case where the resist pattern shows a rightward offset relative to the underlying structure is illustrated. Consequently, as shown in FIG. 2(3), the locations of the gate electrodes relative to the underlying patterns on the left side are different from those on the right side. With a central portion as a boundary, a leftward offset (indicated by “−”) is generated on the left side and a rightward offset (indicated by “+”) is generated on the right side.

Such device characteristics as dark current and white spot in the solid-state image sensing apparatus 1X are degraded to some extent by the offsets as above-mentioned. In this case, however, the pixel characteristics of the solid-state image sensing apparatus 1X having the device characteristics are substantially constant, or the difference in the device characteristics varies gradually with the pixel position. Therefore, the difference is rather inconspicuous.

However, when exposure is conducted twice for manufacturing a large-sized solid-state image sensing apparatus 1X, the boundary between the two exposure areas is located at the center of the solid-state image sensing apparatus 1X. Therefore, a difference in device characteristics is generated between the left-side exposure area and the right-side exposure area, due to the difference in offset amount between the areas located respectively on the left side and the right side of the boundary line, or the like factors. The difference in device characteristics may be inconspicuous if the difference varies gradually. When exposure of the left-side region and exposure of the right-side region are carried out individually, however, the boundary is generated on a straight line and, therefore, a distinct difference in device characteristics is generated. As a result, a step in output is generated between the left side and the right side of the boundary, to be observed as a bright line or a black line or the like. Thus, the boundary would be conspicuously seen.

While the problem has been described referring to the case of the solid-state image sensing apparatus 1, the problem of the step (difference in level) in characteristics which is generated at the boundary area upon application of the region dividing and joining method is not limited to the case of the solid-state image sensing apparatus 1 but is generated also in the cases of general semiconductor apparatuses. In the case of a signal processing system such that the steps in characteristics come to appear in an output signal at random, the steps in characteristics may be averaged on the whole so that they will not matter. However, in the cases of memory devices such as RAM (random access memory) or ROM (read-only memory) where the devices are arrayed in two dimensions and a signal processing system dealing with the signals obtained from the devices deals with the signals on a two-dimensional basis, a step in characteristics is considered to be observed conspicuously, like in the case of the solid-state image sensing apparatus 1.

<Fundamentals of Manufacturing Methods According to Present Embodiment>

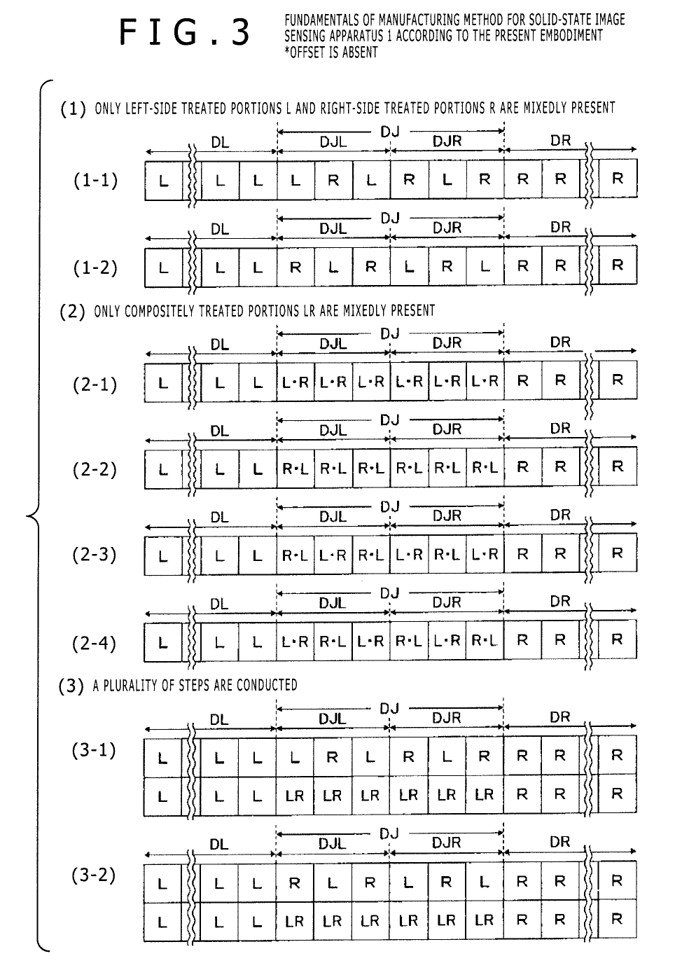

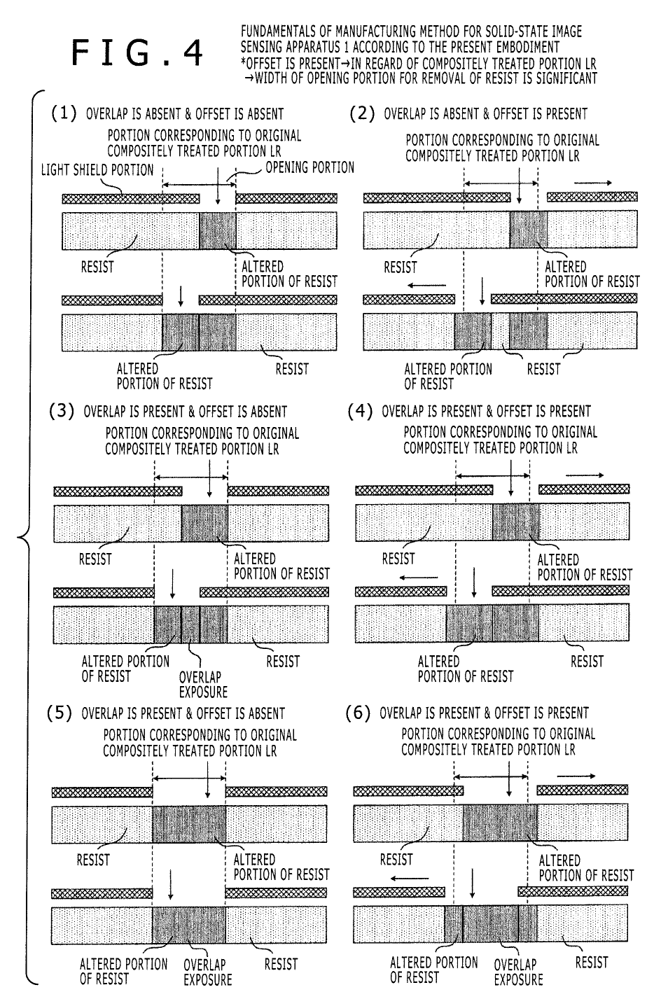

FIGS. 3 to 6 show diagrams for illustrating the fundamentals of the manufacturing method according to the present embodiment, in which attention is paid to the joint domain DJ in the vicinity of the boundary line in manufacturing the whole of a solid-state image sensing apparatus by dividing the whole into a plurality of regions. FIG. 3 illustrates the fundamentals of the mechanism of the present embodiment, wherein attention is paid to device characteristics. FIGS. 4 to 6 illustrate the fundamentals of the mechanism of the present embodiment, wherein attention is paid to opening portions and shield portions (light shield portions) of masks. Hereinafter, description will be made of the case where the whole region of a solid-state image sensing apparatus 1 is divided into a left-side region and a right-side region in performing exposure and ion implantation by dividing the whole region into two divisional regions. This mode of division may not necessarily be adopted, and the whole region may be divided into an upper-side region and a lower-side region.

In the embodiments of the present invention (the present embodiment), as a countermeasure against the above-mentioned problem, in a left-side treatment (one-side treatment) conducted primarily for a left-side domain DL (one-side divisional region), at least part of one-side device portions are formed also in a joint domain DJ. Thereafter, in a right-side treatment (other-side treatment) conducted primarily for a right-side domain DR (other-side divisional region), at least part of other-side device portions are formed in spaces between the one-side device portions in the joint domain DJ. The expression “at least part (of)” is used here in consideration of compositely treated portions LR which will be described later. In the case where left-side treated portions L and right-side treated portions R which will be described later are formed, the whole of each of the device portions is thereby formed.

This ensures that, in the joint region (joint domain DJ) in the vicinity of the boundary in the semiconductor apparatus, the device portions formed simultaneously by the left-side treatment (exposure and ion implantation conducted primarily for the left-side domain DL) and the device portions formed simultaneously by the right-side treatment (exposure and ion implantation conducted primarily for the right-side domain DR) are formed to be mixedly present. In other words, in the joint domain in the vicinity of the boundary, the exposure or ion implantation areas by the left-side treatment and the exposure or ion implantation areas by the right-side treatment are formed to be mixedly present. Patent Document 1 discloses a mechanism of joining through an overlap portion, namely, a mechanism in which overlap exposure is conducted at the to-be-joined position (joint portion) so as to provide a double-exposure area. However, the mechanism of the present embodiment is different from the disclosed mechanism in that it is not based on overlap exposure of the same portion.

[Device Characteristics in Joint Domain]

As shown in FIG. 3, when attention is paid to the joint domain DJ, not only the device portions formed by the left-side treatment (exposure and ion implantation for the original left-side domain DL) but also the device portions formed simultaneously by the right-side treatment (exposure and ion implantation for the right-side domain DR) are present on the left side of the center of the joint domain DJ. On the right side of the center, not only the device portions formed by the right-side treatment (exposure and ion implantation for the original right-side domain DR) but also the device portions formed simultaneously by the left-side treatment (exposure and ion implantation for the left-side domain DL) are present. For this selective formation, a so-called mask (a pattern mask, a residual resist or the like) is used in the exposure step and the ion implantation step.

The device portions in the joint domain DJ are not limited to those in which each object portion is wholly formed in the right-side joint domain DJR simultaneously by the left-side treatment and those in which each object portion is wholly formed in the left-side joint domain DJL simultaneously by the right-side treatment. Specifically, the device portions include those obtained by a process in which the whole of each object portion is formed in the left-side domain DL and part of each object portion is formed in the joint domain DJ by the left-side treatment, and the whole of each object portion is formed in the right-side domain DR and the remainder of each object portion is formed in the joint domain DJ by the right-side treatment, so that the whole of each object portion in the joint domain DJ is formed by composition of part of the object portion and the remainder of the object portion.

For instance, when attention is paid to the left-side joint domain DJL on the left side of the boundary, part of each object portion is formed in the left-side joint domain DJL by the left-side treatment, and the remainder of each object portion is formed in the left-side joint domain DJL simultaneously by the right-side treatment, whereby the whole of each object portion in the left-side joint domain DJL is formed by composition of the part and the remainder of each object portion. When attention is paid to the right-side joint domain DJR on the right side of the boundary, part of each object portion is formed in the right-side joint domain DJR by the right-side treatment, and the remainder of each object portion is formed in the right-side joint domain DJR simultaneously by the left-side treatment, whereby the whole of each object portion in the right-side joint domain DJR is formed by composition of the part and the remainder of each object portion.

In either of the above cases, the treatment zones overlap each other in the joint domain DJ, but, in terms of each object portion, no part is basically treated in an overlapped manner. The expression “basically” is used here in consideration of the fact that an intentional overlap of treatments may be adopted when the offset is taken into account.

In the figures, the left-side treated portions L in which each object portion is wholly formed by the left-side treatment are denoted by “L” marked with a circle, and the right-side treated portions R in which each object portion is wholly formed by the right-side treatment are denoted by “R” marked with a circle. Besides, the compositely treated portions LR in which part of each object portion is formed by the left-side treatment and the remainder of each object portion is formed by the right-side treatment so that the whole of each object portion is formed by composition of the part and the remainder of each object portion are denoted by “LR” marked with a circle.

Paying attention to a given step, the left-side treated portions L and the right-side treated portions R are portions in which the whole of each object portion is formed by performing exposure and ion implantation once, whereas the compositely treated portions LR are portions in which the whole of each object portion is formed by composition of a portion formed by one run of exposure and ion implantation and another portion formed by another run of exposure and ion implantation.

Thus, paying attention to a given step, the compositely treated portion LR may be a portion in which part thereof has the same characteristics as those of the left-side treated portions L and the remainder thereof has the same characteristics as those of the right-side treated portions R; in this case, the portion having the characteristics of the left-side treated portion L and the portion having the characteristics of the right-side treated portion R may be laid out arbitrarily. For instance, where the whole of the object portion is represented by a rectangle, the respective portions of each object portion can be laid out in any of the following modes, in relation to the center of the rectangle.

For example, there may be considered a compositely treated portion L·R in a mode in which the portion having the characteristics of the left-side treated portions L is laid out on the left side whereas the portion having the characteristics of the right-side treated portions R is laid out on the right side, and a compositely treated portion R·L in a mode in which the portion having the characteristics of the left-side treated portions L is laid out on the right side whereas the portion having the characteristics of the right-side treated portions R is laid out on the left side. Further, there may be considered a compositely treated portion L/R in a mode in which the portion having the characteristics of the left-side treated portions L is laid out on the upper side whereas the portion having the characteristics of the right-side treated portions R is laid out on the lower side, and a compositely treated portion R/L in a mode in which the portion having the characteristics of the left-side treated portions L is laid out on the lower side whereas the portion having the characteristics of the right-side treated portions R is laid out on the upper side.

In a practical manufacturing process, masks are used in tens of steps, inclusive of the steps for resist formation by an exposure step or for an ion implantation step. In this case, the combination of the left-side treated portions L, the right-side treated portions R and the compositely treated portions LR can be arbitrarily selected for each step, and the results thereof determine the overall characteristics of the object portions. Herein, the object portions formed upon application of the region dividing and joining method to a plurality of steps are denoted by uppercase letters or lowercase letters with a combination (indicated by “+”) of “L” standing for the left-side treated portion L, “R” standing for the right-side treated portion, and “LR” standing for the compositely treated portion LR. For instance, in the case where the first step yields the characteristics of the left-side treated portions L, the second step yields the characteristics of the compositely treated portion LR and the third step yields the characteristics of the right-side treated portion R, the object portion is represented as a compositely treated portion L+LR+R.

A first example shown in FIG. 3(1) corresponds to the case where each object portion is wholly formed by only one of the left-side treatment inclusive of exposure and ion implantation and the right-side treatment inclusive of exposure and ion implantation, the two kinds of treated portions being present in a mixed state. In a typical example of this, only the left-side treated portions L and the right-side treated portions R are alternately arranged. Especially, in FIG. 3(1-1), the left-side treated portions L are laid out to be partialized to the left side and the right-side treated portions R are laid out to be partialized to the right side. In FIG. 3(1-2), the left-side treated portions L are laid out to be partialized to the right side and the right-side treated portions R are laid out to be partialized to the left side. Incidentally, in forming the left-side treated portions L and the right-side treated portions R, the left-side and right-side treated portions L, R are basically formed respectively by one left-side treatment and one right-side treatment (two treatments in total). This, however, does not preclude the case where the object portion to be treated by the left-side treatment or the right-side treatment is further divided into a plurality of portions and where three or more treatments in total are carried out.

A second example shown in FIG. 3(2) corresponds to the case where the whole of each object portion is formed only of a compositely treated portion LR and where only the compositely treated portions LR are arranged. Especially, FIG. 3(2-1) shows a configuration in which only compositely treated portions L·R are arranged, and FIG. 3(2-2) shows a configuration in which only compositely treated portions R·L are arranged. FIG. 3(2-3) shows a configuration in which compositely treated portions L·R are laid out to be partialized to the left side and compositely treated portions R·L are laid out to be partialized to the right side. FIG. 3(2-4) shows a configuration in which compositely treated portions L·R are laid out to be partialized to the right side and compositely treated portions R·L are laid out to be partialized to the left side. Though not shown, there may also be adopted a layout in which the compositely treated portions L·R and the compositely treated portions R·L in the just-mentioned configurations are replaced respectively by compositely treated portions L/R and compositely treated portions R/L, and a layout in which is adopted an arbitrary combination of a compositely treated portion L·R, a compositely treated portion R·L, a compositely treated portion L/R and a compositely treated portion R/L. Incidentally, in forming the compositely treated portions LR, composition of one left-side treatment and one right-side treatment (two treatments in total) is basically adopted. This, however, does not preclude the case where the object portion to be treated by the left-side treatment or the right-side treatment is further divided into a plurality of portions and where three or more treatments in total are carried out to form the compositely treated portions.

In a third example shown in FIG. 3(3), attention is paid to a plurality of steps such as an exposure step and an impurity ion implantation step for forming device regions (active regions and isolation regions) or for forming electrodes. As for the joint domain DJ, a first step shown on the lower side in the figure produces a condition where only compositely treated portions LR are arranged, and a second step shown on the upper side produces a condition where only left-side treated portions L and right-side treated portions R are alternately arranged. Consequently, the compositely treated portions LR+L and the compositely treated portions LR+R are arranged in the joint domain DJ as a whole. Particularly, FIG. 3(3-1) corresponds to a combination with FIG. 3(1-1), while FIG. 3(3-2) corresponds to a combination with FIG. 3(1-2).

In each drawing of FIG. 3, only the left-side treated portions L are present in the left-side domain DL, while only the right-side treated portions R are present in the right-side domain DR. In the joint domain DJ, the two kinds of treated portions composed of the left-side treated portions L and the right-side treated portions R are mixedly present, or only the compositely treated portions LR are present, or a combination of them is adopted. In any of these cases, the solid-state image sensing apparatus 1 produced by one of these manufacturing methods shows a configuration in which device portions formed simultaneously by the left-side treatment and device portions formed simultaneously by the right-side treatment are mixedly present in the joint domain DJ in the vicinity of the boundary.

The first example is advantageous in that the left-side treated portions L in the joint domain DJ are the same as the left-side treated portions L in the left-side domain DL in device characteristics and that the right-side treated portions R in the joint domain DJ are the same as the right-side treated portions R in the right-side domain DR in device characteristics. The first example, however, is disadvantageous in that the array pitch corresponds to one pixel amount and, therefore, the degree of mixing of device characteristics in the joint domain DJ is poorer than that in the second example. The second example is advantageous in that when there is no offset, the array pitch corresponding to ½ pixel amount ensures a better degree of mixing of device characteristics in the joint domain DJ than that in the first example. The second example, however, is disadvantageous in that when an offset is present, a device characteristic in the joint domain DJ is not equal to simple composition of those of the left-side treated portion L and the right-side treated portion R, as described later. The third example is advantageous in that the final device characteristics in the joint domain DJ are determined by a combination of a plurality of steps and, therefore, it is easier to control the degree of mixing of device characteristics than in the first and second examples.

[Opening Portions and Light Shield Portions of Masks in Joint Domain]

In order to ensure that one-side device portions and other-side device portions are mixedly present in the joint domain DJ, as the left-side treatment mask to be used in the left-side treatment and the right-side treatment mask to be used in the right-side treatment, masks differing from each other in the layout of the opening portions and shield portions in the joint domain DJ are used (details of this will be described in embodiments below). Here, the left-side treated portions L and the right-side treated portions R are portions in which each object portion is wholly formed by one run of exposure and ion implantation. Therefore, the opening width in the mask used for forming these portions is the same for all of the left-side domain DL, the right-side domain DR, and the joint domain DJ.

On the other hand, the compositely treated portions LR are portions in which the whole of the device is formed by composition of a portion formed by one run of exposure and ion implantation and another portion formed by another run of exposure and ion implantation, and, therefore, the mask opening width in the joint domain DJ is different from that (or those) in the left-side domain DL and the right-side domain DR. In this connection, in the case where the opening portions for exposure to light or ion implantation are significant, each opening portion is treated in the state of being divided into a plurality of divisional portions. In this case, as for the light shield portion, whether or not a light shield portion in one run of exposure and a corresponding light shield portion in another run of exposure overlap each other is insignificant. On the other hand, in the case where the light shield portions are significant, each light shield portion is treated in the state of being divided into a plurality of divisional portions. In this case, whether or not an opening portion in one run of exposure and a corresponding opening portion in another run of exposure overlap each other is insignificant. In other words, in the case where a specific portion of each device is formed by composition of a one-side device portion formed by the left-side treatment and an other-side device portion formed by the right-side treatment, it is at least ensured that the opening portion for one device is provided divisionally in the left-side treatment mask and in the right-side treatment mask. The portion to be a shield portion is set as a shield portion in each of the masks.

Incidentally, while it has been assumed that the offset is zero in the above description, it is very difficult in practice to reduce the alignment (joining) error (offset) to zero. If a discrepancy in alignment (registration) is generated, it would cause line breakage in electrodes or wiring, or breakage or isolation failure in active regions or isolation regions. Therefore, in the case where one opening portion or one light shield portion is treated divisionally by a plurality of runs of treatment and a specific portion of each device is formed by composition of a one-side device portion and an other-side device portion, overlap (superposition) is adopted by taking into account the offset. Where the shield portion is significant, the relevant portion is set to be a shield portion in every run of exposure. Where the opening portion is significant, an opening portion in a one-side treatment mask and an opening portion in an other-side treatment mask are made to overlap each other when there is no offset between the one-side treatment mask and the other-side treatment mask.

Incidentally, the amount of overlap (superposition) is dependent on not only the offset but also whether significance is connected to the width of a certain portion of the device constituting a physical aspect or significance is connected to the concentration of a certain impurity constituting a process aspect. In view of this, the layouts of masks are controlled according to the extent of requirements. In other words, the layouts of masks for the joint domain DJ are regulated according to what part of the sizes of patterns to be formed is important from the viewpoint of accuracy and impurity concentration characteristics.

For example, in FIG. 4, attention is paid to the case where the width of an opening portion for removal of a resist is significant. As seen from comparison of FIG. 4(1) with FIG. 4(2), where division is made without providing an overlap between corresponding opening portions, an offset may cause an exposure error at a portion corresponding to an original compositely treated portion LR, leading to line breakage in an electrode or wiring.

In view of this, taking into account the offset between the resist masks for respective treatments, it is recommendable to perform overlap exposure at the alignment position of opening portions divisionally related respectively to two treatments of the joint domain DJ when no offset is present, as shown in FIG. 4(3). In other words, the left-side treatment mask (one-side treatment mask) is provided with an opening portion in the whole of each portion corresponding to the left-side treated portion L (one-side device portions) and in at least part of each portion corresponding to the right-side treatment portions R (other-side device portions). The right-side treatment mask (other-side treatment mask) is provided with an opening portion in the whole of each portion corresponding to the right-side treated portions R (other-side device portions) and in at least part of each portion corresponding to the left-side treated portions L (one-side device portions).

This ensures that even when an offset is generated within an overlap range, as shown in FIG. 4(4), failure in exposure at the alignment position can be obviated. While the resist in an area where it is irradiated with light is altered to be easy to remove by a liquid chemical, exposure of the same resist portion to light a plurality of times will only slightly change the degree of alteration and it will not influence the resist removing performance. Therefore, in the case where formation of patterns by exposure to light is significant, masks with the same opening width for the joint domain DJ may in extreme cases be used in all runs of exposure, as shown in FIGS. 4(5) and 4(6).

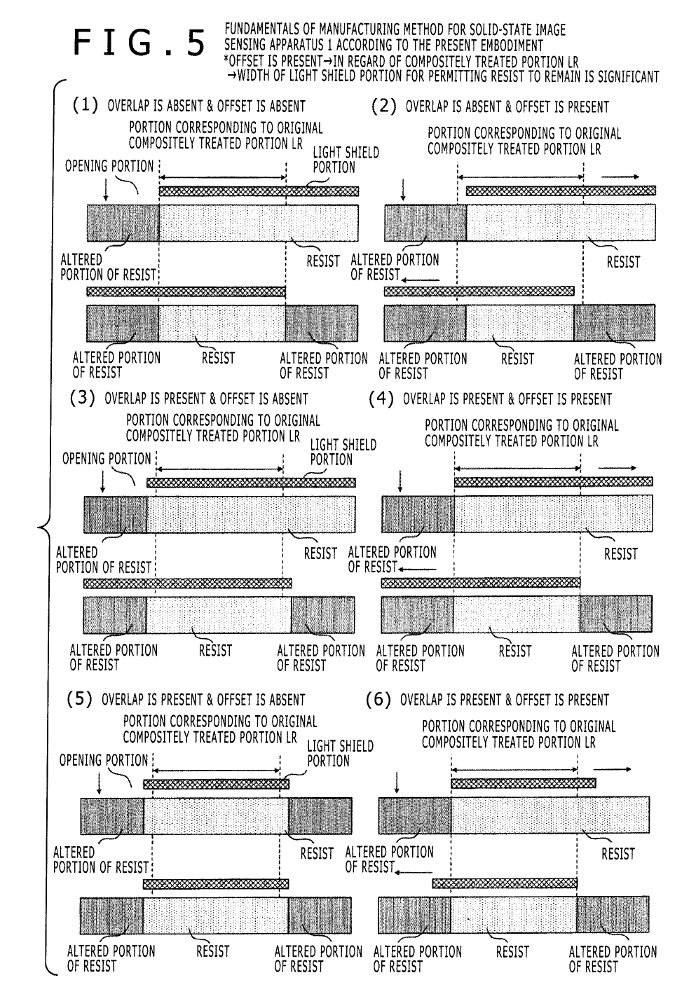

FIG. 5 shows diagrams in which attention is paid to the case where the width of each light shield portion for permitting the resist to remain is significant. As seen from comparison of FIG. 5(1) with FIG. 5(2), if the masks are divisionally prepared without any overlap between the whole bodies of the light shield portions of the masks, the presence of an offset causes an exposure error in a portion corresponding to an original compositely treated portion LR, leading to line breakage in an electrode or wiring.

In view of this, taking into account the offset between a left-side treatment resist mask and a right-side treatment resist mask, it is recommendable to ensure that non-exposed portions (the whole bodies of original light shield portions) overlap securely each other at the alignment position of the light shield portions divisionally prepared for two treatments of the joint domain DJ when there is no offset, as shown in FIG. 5(3). In other words, a left-side treatment mask is provided with a shield portion which is wider than the whole of a portion corresponding to a specific portion of each device, and a right-side treatment mask is also provided with a shield portion which is wider than the whole of a portion corresponding to a specific portion of each device.

This ensures that even when an offset is generated, unintended exposure to light at the alignment position can be obviated, as shown in FIG. 5(4). In this case, the overlap portion is a portion where the resist is shielded from light and, therefore, will not influence the remaining performance of the resist. Therefore, masks with the same light shield width for the joint domain DJ may in extreme cases be used in all runs of exposure, as shown in FIGS. 5(5) and 5(6).

In FIG. 4 and FIG. 5, consideration has been made while paying attention to the opening portion and the light shield portion in a divisional manner. However, the opening portion and the light shield portion are in a duality relation. Consequently, therefore, it suffices to advance consideration referring to either one of FIG. 4 and FIG. 5. Besides, while the descriptions of the photolithography steps referring to FIG. 4 and FIG. 5 have been made based on the positive type in which the resist portions irradiated with light are removed, the above descriptions are naturally inverted in the case of the negative type in which the resist portions shielded from light are removed.

For instance, in the case where the width of the light shield portion for removal of the resist is significant, the overlap portion is a portion shielded from light and, therefore, it will not influence the resist removing performance. In extreme cases, masks with the same light shield width for the joint domain DJ can be used in all runs of exposure. In the case where the width of the opening portion for allowing the resist to remain is significant, the resist in an area where it is irradiated with light is altered to be difficult to remove by a liquid chemical. In this case, exposure of the same resist portion to light a plurality of times will only slightly change the degree of alteration and it will not affect the remaining performance of the resist. In extreme cases, masks with the same opening width for the joint domain DJ can be used in all runs of exposure.

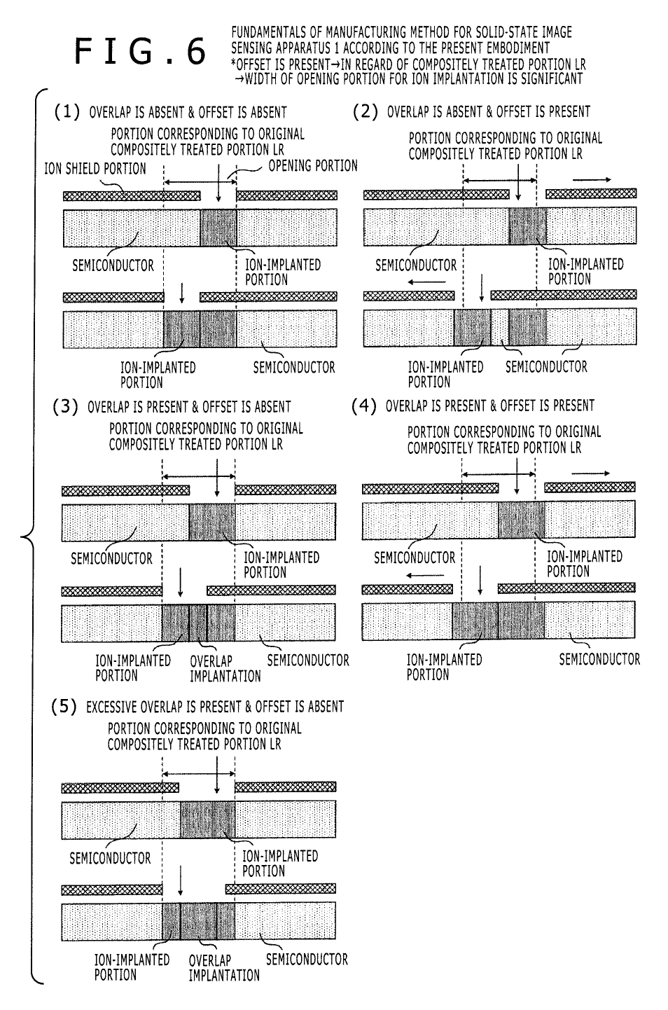

FIG. 6 shows diagrams in which attention is paid to the case where the width of each opening portion for ion implantation is significant. As seen from comparison of FIG. 6(1) with FIG. 6(2), if the masks are divisionally prepared without any overlap between the opening portions of the masks, the presence of an offset causes an ion-implantation error in an area corresponding to an original compositely treated portion LR, possibly leading to breakage or isolation failure at an active region or an isolation region. In view of this, it is recommendable to perform overlap ion implantation at the registration position of the opening portions divisionally prepared for two treatments of the joint domain DJ when there is no offset, as shown in FIG. 6(3).

This ensures that even when an offset is generated within the overlap range, failure in ion implantation at the alignment position can be obviated, as shown in FIG. 6(4). It should be noted here, however, that when the same portion is subjected to ion implantation a plurality of times, a difference in impurity concentration is induced, which influences the device characteristics. When excessive overlap is present, as shown in FIG. 6(5), the area of a different impurity concentration increases, leading to a large difference in device characteristics. Therefore, it is essentially recommendable to avoid such overlap of ion implantations. Even where the offset is taken into account, it is recommendable to obviate excessive overlap and to ensure that overlap in an extent corresponding to the offset amount is provided for the joint domain DJ.

This means the following. It is desirable to avoid overlap of opening portions, at least in the ion implantation steps. Besides, in the case where ion implantation through opening portions is significant, the use of masks with the same opening width in all runs of ion implantation is not allowed. In other words, it is essential that at least in the ion implantation steps, a left-side treatment mask and a right-side treatment mask should securely be set to be different in the layout relation between the opening portions and the shield portions in the joint domain DJ.

As presumed from FIGS. 4 to 6, in the case of applying the compositely treated portion LR, the width of each object portion in the joint domain DJ, when a registration error (offset) is taken into account, is different from the width of each object portion in the left-side domain DL and the right-side domain DR. The influence of this will appear as a difference in device characteristics. In the case of applying the region dividing and joining method, it is recommendable that whether each object portion in the joint domain DJ is composed of object portions of the left-side domain DL and the right-side domain DR or composed of the compositely treated portions LR should be determined according to what part of the sizes of patterns to be formed is of importance in terms of accuracy and/or characteristics. Specifically, of the object portions in the joint domain DJ, those which are of importance in terms of accuracy and/or characteristics are preferably composed of object portions of the left-side domain DL and the right-side domain DR, whereas those which are of little importance in terms of accuracy and/or characteristics are preferably composed of the compositely treated portions LR.

As has been described above, the solid-state image sensing apparatus 1 according to the present embodiment is characterized in that device portions formed by exposure and ion implantation on the left side and device portions formed by exposure and ion implantation on the right side are mixedly present in the joint domain DJ. Since the portions formed by the left-side shot (exposure and ion implantation) and the portions formed by the right-side shot are mixedly present in the joint domain DJ, both the characteristics of the left-side treated portion L and the characteristics of the right-side treated portion R are mixedly present in the joint domain DJ as a whole.

If no offset is present upon divisional formation, the left-side treated portions L and the right-side treated portions R and the compositely treated portions LR have uniform device characteristics, respectively. In practice, however, the offset cannot be reduced to zero and, therefore, not a little difference in characteristics is present in these portions. In the solid-state image sensing apparatus 1 according to this embodiment, however, both the characteristics of the left-side treated portion L and the characteristics of the right-side treated portion R are mixedly present in the joint domain DJ as a whole, whereby the step (difference in level) in output between the left side and the right side of the boundary can be reduced (in other words, contrast can be shaded), so that the difference in characteristics at the boundary portion can be made inconspicuous.

### First Embodiment

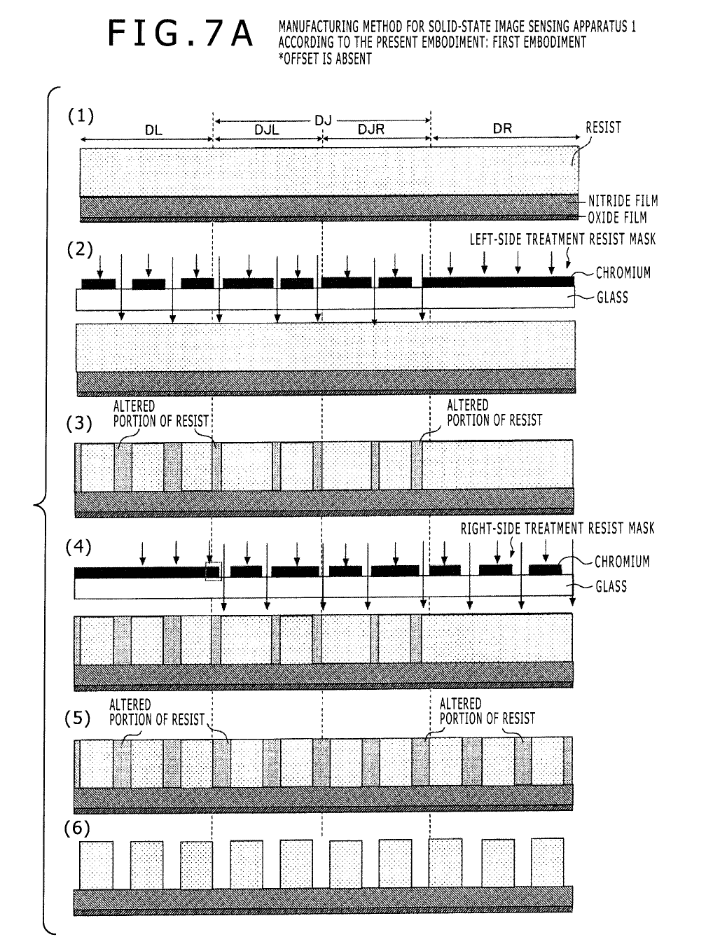

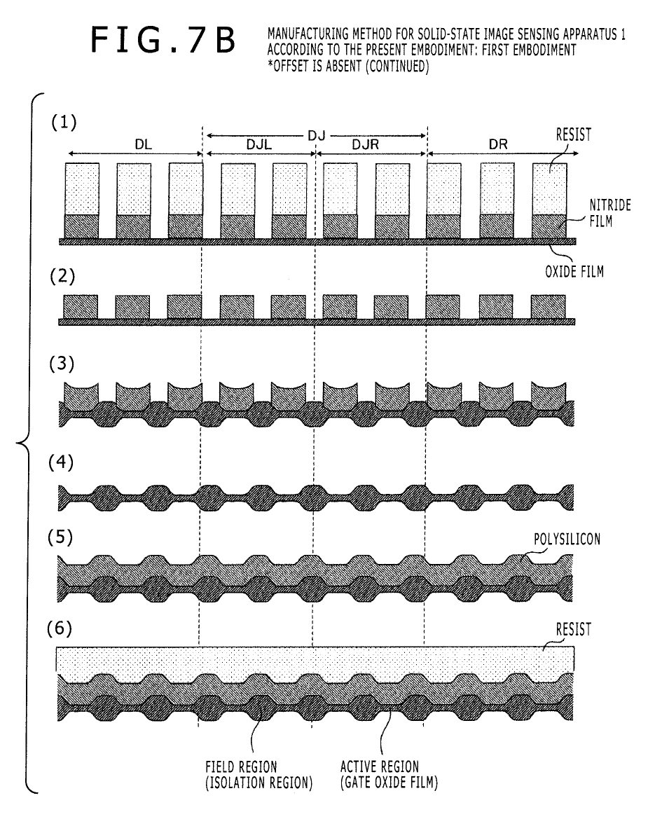

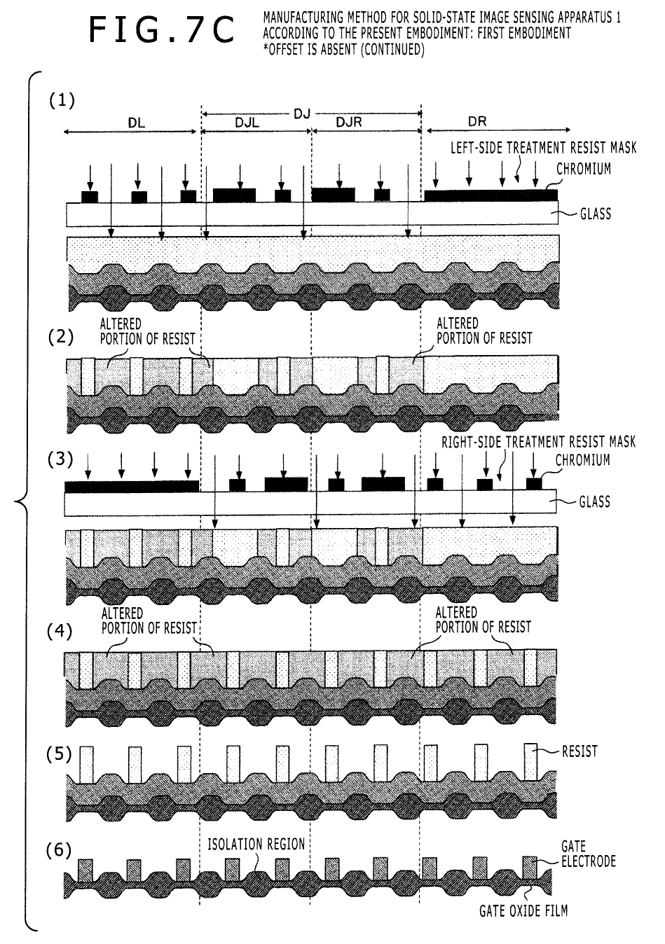

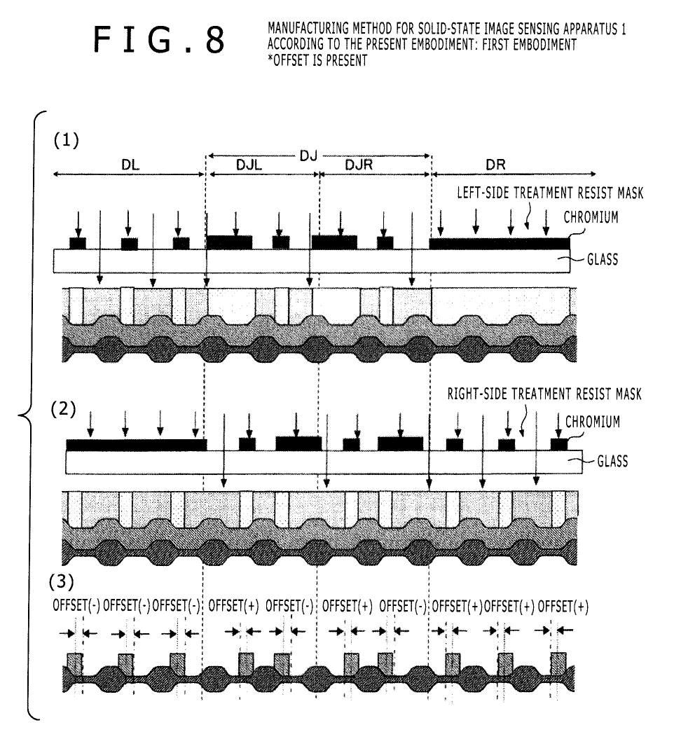

FIGS. 7A to 8 show diagrams for illustrating a manufacturing method according to a first embodiment of the present invention. Here, FIGS. 7A to 7C correspond to the case where there is no offset of gate electrodes relative to active regions, whereas FIG. 8 corresponds to the case where there is an offset of gate electrodes relative to active regions.

The first embodiment pertains to the case where isolation regions are formed by application of the LOCOS method, the width of fields for the isolation regions in the joint domain DJ is determined by composition of two shots of exposure, and the width of gate electrodes formed in register to the active region patterns in the joint domain DJ is determined by one run of exposure. Specifically, in this case, the isolation regions are formed by applying the second example shown in FIG. 3(2), whereas the gate electrodes are formed by applying the first example shown in FIG. 3(1).

[Where Offset is Absent]

FIGS. 7A and 7B illustrate steps pertaining to formation of isolation regions by application of the LOCOS method. First, an oxide film and a nitride film are formed over a silicon wafer, and a positive-type resist is applied to the nitride film (FIG. 7A(1)).

Next, a left-side treatment and a right-side treatment are each carried out by use of a resist mask placed over the resist. In this case, by application of the second example shown in FIG. 3(2), each of isolation regions as object portions in a joint domain DJ is formed by forming only a compositely treated portion LR. For this purpose, the resist masks have mask patterns such that each of opening portions in the joint domain DJ is treated in the state of being bisected (into halves) by the left-side treatment and the right-side treatment.

As an example, in the figure, compositely treated portions L·R and compositely treated portions R·L are alternately arrayed, in the manner of the compositely treated portion L·R, the compositely treated portion R·L, the compositely treated portion L·R, the compositely treated portion R·L, and the compositely treated portion L·R in this order from the left side toward the right side in the joint domain DJ. In this layout, the compositely treated portions LR in different modes are arrayed alternately.

Where an offset between a left-side treatment resist mask and a right-side treatment resist mask is taken into account, the width of each of the bisected opening portions in the joint domain DJ is preferably set to be larger than one half of the normal opening width so that overlap exposure occurs at the alignment position.

Exposure is conducted by arranging the left-side treatment resist mask over the resist (FIG. 7A(2)). In this instance, while the right-side domain DR is shielded from light, not only the whole of each isolation region in the left-side domain DL and one half of each isolation region in the left-side joint domain DJL but also one half of each isolation region in the right-side joint domain DJR is exposed to light through the opening portions. FIG. 7A(3) illustrates the condition of altered portions of the resist after exposure to light in the left-side treatment.

Next, the left-side treatment resist mask is removed, the right-side treatment resist mask is arranged over the resist, and exposure is carried out (FIG. 7A(4)). In this instance, while the left-side domain DL is shielded from light, not only the whole of each isolation region in the right-side domain DR and one half of each the isolation region in the right-side joint domain DJR but also the remaining half of each isolation region in the left-side joint domain DJL is exposed to light through the opening portions. FIG. 7A(5) illustrates the condition of altered portions of the resist after exposure to light in the right-side treatment.

Subsequently, the altered layer at the resist portions exposed to light is removed by a liquid chemical in a developing step in lithography (FIG. 7A(6)). Next, dry etching is conducted using the remaining resist as a mask, whereby portions of the nitride film (the portions in the field regions corresponding to the isolation regions) are removed (FIG. 7B(1)). Further, the resist on the nitride film which is remaining is removed by ashing or treatment with a liquid chemical, whereby the nitride film remaining in other areas than the field regions is exposed (FIG. 7B(2)).

Subsequently, field oxidation (LOCOS oxidation) for oxidizing the oxide film by using the nitride film exposed in other areas than the field regions as a mask is conducted, whereby a gate oxide formed on the silicon wafer and a LOCOS oxide film are formed (FIG. 7B(3)). In the field oxidation, oxidation of the portions corresponding to the active regions where the nitride film is formed does not proceed, and only oxidation of the portions corresponding to the field regions where the nitride film is absent proceeds. As a result, the thickness of the oxide film is reduced at the portions corresponding to the active regions, and is enlarged at the portions corresponding to the field regions. The oxide film portions corresponding to the field regions thus enlarged in film thickness will function as isolation regions.

Thereafter, the nitride film on the LOCOS oxide film is peeled off (FIG. 7B(4)). Furthermore, polysilicon or the like as a material for gate electrodes is formed on the LOCOS oxide film serving as underlying patterns, by a process technique such as CVD (FIG. 7B(5)). Then, a positive-type resist as a material for forming resist patterns by photolithography is applied to the polysilicon (FIG. 7B(6)). The condition thus obtained is the condition of FIG. 1(1) shown in the manufacturing method according to the comparative example.

FIG. 7C illustrates steps relating to the formation of gate electrodes in active regions. A left-side treatment and a right-side treatment are each conducted by placing over a resist a resist mask in which portions corresponding to the gate electrodes are formed as light shield portions. In this case, by applying the first example shown in FIG. 3(1), the light shield portions at portions corresponding to the gate electrodes which are object portions in a joint domain DJ are each composed only of a left-side treated portion L or a right-side treated portion R.

Therefore, the resist masks are provided with mask patterns such that the portions corresponding to the gate electrodes in the joint domain DJ are light shield portions in both the left-side treatment and the right-side treatment, whereas the other portions than the gate electrodes are opening portions in at least one of the left-side treatment and the right-side treatment. In other words, each of the masks has a configuration in which a light shield portion is provided at a portion corresponding to the whole of each of the left-side treated portions L and the right-side treated portions R corresponding to the gate electrodes, and an opening portion is provided at each of the other portions. If only the light shield portions satisfy this relationship, the widths of the opening portions for removal of the resist may be set in any way.

As an example, portions of the joint domain DJ which are located in the order from the left side toward the right side are treated as follows. First, the left-side treated portions L are arranged by providing a left-side treatment resist mask with such a structure that the light shield portions corresponding to the first and third gate electrodes are wider than the gate electrode width and that the light shield portions corresponding to the second and fourth gate electrodes have the gate electrode width. Besides, the right-side treated portions R are arranged by providing a right-side treatment resist mask with such a structure that the light shield portions corresponding to the second and fourth electrode gates are wider than the gate electrode width and that the light shield portions corresponding to the first and third gate electrodes have the gate electrode width. In this layout, the left-side treated portions L and the right-side treated portions R are arranged alternately. When an offset between the masks is taken into account, the width of each of the bisected opening portions in the joint domain DJ is set to be larger than one half of the normal opening width, as shown in FIG. 4 above, so that overlap exposure occurs at the alignment position when the offset is absent.

Exposure is conducted by placing the left-side treatment resist mask over the resist (FIG. 7C(1)). While the right-side domain DR is shielded from light, not only other portions than the gate electrodes in the left-side domain DL and the left-side joint domain DJL but also other portions than the gate electrodes in the right-side joint domain DJR are exposed to light through the opening portions. FIG. 7C(2) shows the condition of altered portions of the resist after exposure to light in the left-side treatment.

Exposure is carried out by placing the right-side treatment resist mask over the resist (FIG. 7C(3)). While the left-side domain DL is shielded from light, not only other portions than the gate electrodes in the right-side domain DR and the right-side joint domain DJR but also other portions than the gate electrodes in the left-side joint domain DJL are exposed to light through the opening portions. FIG. 7C(4) shows the condition of altered portions of the resist after exposure to light in the right-side treatment.

Next, the altered layer at the resist portions exposed to light is removed by a liquid chemical in a developing step in lithography (FIG. 7C(5)).

Subsequently, portions of the polysilicon layer (the other portions than the gate electrodes) are removed by dry etching using the remaining resist as a mask. Further, the resist on the polysilicon which is remaining is removed by ashing, whereby the gate electrodes are exposed (FIG. 7C(6)).

[Where Offset is Present]

The above description pertains to the case where there is no offset of the gate electrodes relative to the active regions of the LOCOS oxide film which are underlying patterns. In a practical manufacturing process, however, an offset of the gate electrodes relative to the underlying patterns is generated. FIG. 8 illustrates a situation upon generation of an offset. When exposure in the left-side treatment for the solid-state image sensing apparatus 1 is conducted, as shown in FIG. 8(1), an offset of the resist pattern relative to the underlying structure is generated. Here, a case where the resist pattern shows a leftward offset is illustrated.

Next, as shown in FIG. 8(2), exposure for the right-side half is conducted. Here, a case where the resist pattern shows a rightward offset is illustrated. Consequently, as shown in FIG. 8(3), differences in the positions of the gate electrodes relative to the underlying patterns are generated between the left side and the right side.

A manufacturing method according to a comparative example has been illustrated in FIG. 2. In this case, as shown in FIG. 2(3), a leftward offset is generated on the left side and a rightward offset is generated on the right side, with the central portion as a boundary. In contrast, in the manufacturing method according to the first embodiment, as shown in FIG. 8(3), gate electrodes in a leftward offset state based on the left-side treated portions L and gate electrodes in a rightward offset state based on the right-side treated portions R are alternately arrayed in the joint domain DJ in the vicinity of the central portion.

On the basis of characteristics, steps in output (steps in characteristics) according to the respective offsets are generated. In the solid-state image sensing apparatus, however, the gate electrodes are arranged at intervals of several micrometers. Therefore, the line-by-line offsets in characteristics are visually recognized with difficulty, and the leftward and rightward offsets are averaged on a visual basis, so that the steps in characteristics are visually recognized to be slight. In other words, both the characteristics of device portions formed simultaneously by the left-side treatment and the characteristics of device portions formed simultaneously by the right-side treatment are mixedly present in the joint domain DJ as a whole. As a result, the step in output between the left side and the right side of the boundary is visually recognized to be slight; therefore, contrast can be shaded (gradated), and the difference of characteristics in the joint domain DJ (or at the boundary) can be made inconspicuous.

Incidentally, while the above description has been given in comparison to the case where there is an offset of the gate electrodes relative to the active regions of the LOCOS oxide film which are underlying patterns, the offset occurs not only in this situation but also between various steps. For example, an offset may occur between similar steps in the application of the region dividing and joining method itself.

As an example, in the LOCOS oxide film itself constituting the underlying patterns, an offset may be generated between the left-side patterns and the right-side patterns. In this case, an offset is generated as to the widths of the active regions and the isolation regions, so that the transistors obtained show differences in characteristics. When the manufacturing method according to the first embodiment is applied, however, the same effect on the joint domain DJ as the above-mentioned can be obtained, irrespectively of the object area to which the method is applied.

While the above description pertains to the case where an offset is present between the two layers (the LOCOS oxide film layer and the gate electrode layer), a practical manufacturing process may involve offsets during tens of steps inclusive of those for resist formation in ion implantation steps. In such a case, also, if the manufacturing method according to the first embodiment is applied, the same effect on the joint domain DJ as above-mentioned can be obtained, irrespectively of the object area to which the method is applied.

The above description has been made on the assumption that the object area in divisionally forming isolation regions by the LOCOS method while applying the region dividing and joining method according to the present embodiment and the object area in divisionally forming gate electrodes by applying the region dividing and joining method according to the present embodiment are the same area, but this is not indispensable to the present invention. The joint domain DJ in divisionally forming the isolation regions (FIGS. 7A(1) to 7B(5)) and the joint domain DJ in divisionally forming the gate electrodes (FIGS. 7B(6) to 7C(6)) may be different from each other. In addition, for example, there may be a difference, between a pixel array section and a peripheral circuit section, in the object steps (layers) to which the region dividing and joining method according to the present embodiment is applied. In any case, if the manufacturing method according to the first embodiment is applied, the same effect on the joint domain DJ as above-mentioned can be obtained, irrespectively of the object steps or layers to which the method is applied.

As for the mode of layout of device characteristics used in applying the region dividing and joining method according to the present embodiment to a plurality of steps (layers), a combination of the first example (FIG. 3(1)) and the second example (FIG. 3(2)) may be adopted as in the third example (FIG. 3(3)). The manner of combination may not necessarily be the same throughout the whole area of the semiconductor apparatus, and may be different according to respective areas. A difference in the mode of combination may be present between the pixel array section and the peripheral circuit section. In this case, also, if the manufacturing method according to the first embodiment is applied, the same effect on the joint domain DJ as above-mentioned can be obtained, irrespectively of the object area to which the method is applied.

While description has been made of the case where one large-area solid-state image sensing apparatus 1 is manufactured by performing exposure and ion implantation divisionally twice (for two divisional regions), the exposure and ion implantation may be conducted three or more times (for three or more divisional regions) where the apparatus is still larger in area. In this case, also, paying attention to each of divisional regions, it suffices to apply the region dividing and joining method to the joint domain DJ between the adjacent divisional regions, whereby the same effect on the joint domain DJ as above-mentioned can be obtained.

### Second Embodiment

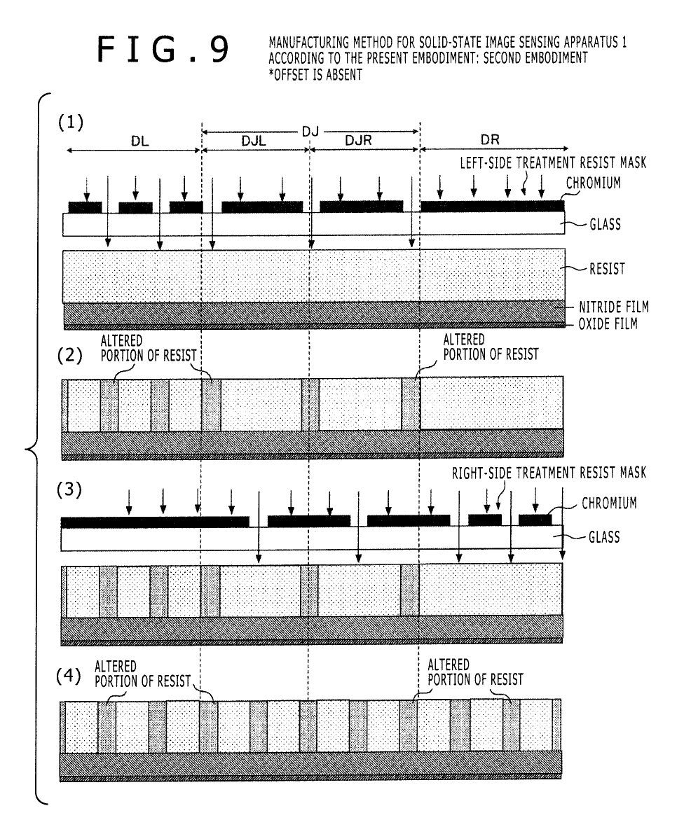

FIG. 9 shows diagrams for illustrating a manufacturing method according to a second embodiment of the present invention. The second embodiment pertains to the case where isolation regions are formed by applying the LOCOS method and where the field width for the isolation regions in a joint domain DJ is determined by one run of exposure. In other words, the formation of the isolation regions in this case is conducted by applying the first example shown in FIG. 3(1). Though omitted in drawing, the width of gate electrodes formed in register to active region patterns is also determined by one run of exposure while applying the first example shown in FIG. 3(1).

A left-side treatment and a right-side treatment are each carried out by placing over a resist a resist mask in which portions corresponding to the gate electrodes are light shield portions. In this case, by applying the first example shown in FIG. 3(1), the isolation regions as object portions in the joint domain DJ are each composed only of a left-side treated portion L or a right-side treated portion R. For this purpose, the resist masks are provided with mask patterns such that portions corresponding to the active regions in the joint domain DJ are light shield portions in each of the treatments and that portions corresponding to field regions (isolation regions) are opening portions in at least one of the treatments. In other words, a left-side treatment mask has a structure in which an opening portion is provided at a portion corresponding to the whole of each left-side treated portion L and in which the other portions are shield portions; similarly, a right-side treatment mask has a structure in which an opening portion is provided at a portion corresponding to the whole of each right-side treated portion R and in which the other portions are shield portions. It suffices that the opening portions satisfy this relationship, and the widths of the light shield portions for permitting the resist to remain may be set in any way.

As an example, portions of the joint domain DJ which are located in the order from the left side toward the right side are treated as follows. Incidentally, a third isolation region is set at the boundary between a left-side joint domain DJL and a right-side joint domain DJR. First, the left-side treated portions L are arranged by providing a left-side treatment resist mask with such a structure that wider light shield portions are arranged at positions corresponding to the second and fourth isolation regions and that opening portions the same in width as the isolation portions are provided at positions corresponding to the first, third and fifth isolation regions. Besides, the right-side treated portions R are arranged by providing a right-side treatment resist mask with such a structure that wider light shield portions are arranged at positions corresponding to the first, third and fifth isolation regions and that opening portions the same in width as the isolation regions are provided at positions corresponding to the second and fourth isolation regions.

Exposure is conducted by placing the left-side treatment resist mask over a resist (FIG. 9(1)). In this instance, while the right-side domain DR is shielded from light, not only the isolation regions in the left-side domain DL and the left-side joint domain DJL but also the isolation regions in the right-side joint domain DJR are exposed to light through the opening portions. FIG. 9(2) shows the condition of altered portions of the resist after exposure to light in the left-side treatment.

Next, the left-side treatment resist mask is removed, the right-side treatment resist mask is arranged over the resist, and exposure is carried out (FIG. 9(3)). In this instance, not only the isolation regions in the right-side domain DR and the right-side joint domain DJR but also the isolation regions in the left-side joint domain DJL are exposed to light through the openings. FIG. 9(4) illustrates the condition of altered portions of the resist after exposure in the right-side treatment.

When the second example shown in FIG. 3(2) is applied, there is a difficulty, when the offset is taken into account, in that the width of the object portions in the joint domain DJ is different from the width of the object portions in the left-side domain DL and the right-side domain DR, generating a difference in device characteristics. Although each object portion is in the condition where both characteristics of a device portion formed by the left-side treatment and characteristics of a device portion formed by the right-side treatment are mixedly present, the characteristics of the object portion as a whole differ depending on the offset. Consequently, the difference of characteristics between the object portions in the joint domain DJ and the object portions in the left-side domain DL and the right-side domain DR varies depending on the offset.

In the case where the accuracy of the widths of the field regions corresponding to the active regions and the isolation regions are not important and where the gate electrode width is the most important, it is recommendable to form the isolation regions by composition of two runs of exposure and to form the gate electrodes by one run of exposure, as in the first embodiment. On the other hand, in the case where the accuracy of the widths of the field regions corresponding to the active regions and isolation regions are important, it is recommendable to form the isolation regions by one run of exposure, as in the second embodiment.

<Example of Application to Solid-State Image Sensing Apparatus>

Now, an outline of the semiconductor apparatuses in the present embodiment which are manufactured by applying the manufacturing methods according to the first and second embodiments will be described below. In the following, particularly, description will be made by paying attention to how to lay out a joint domain DJ relative to an effective image sensing region and a peripheral circuit region of a solid-state image sensing apparatus 1 which is an example of semiconductor apparatus. Incidentally, in the following description, the case where a CMOS-type solid-state image sensing apparatus which is an example of an X-Y address type solid-state image sensing apparatus is used as a device will be taken as an example.

[Schematic Outline]

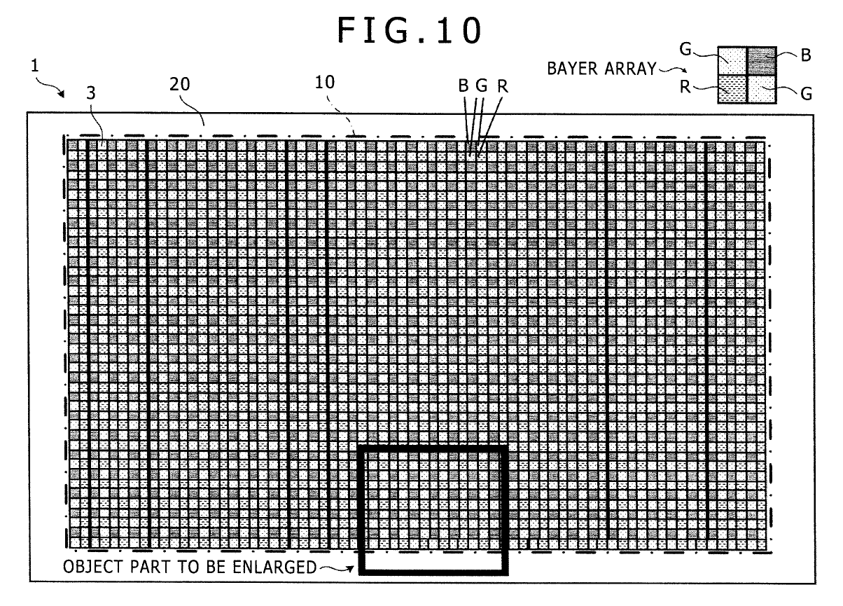

FIG. 10 illustrates a schematic outline of a solid-state image sensing apparatus 1. The solid-state image sensing apparatus 1 has a pixel array section 10 (effective image sensing range) provided as a main circuit section disposed inside the solid-state image sensing apparatus 1 in which a plurality of unit pixels 3 are arranged in a two-dimensional matrix, and a peripheral circuit section 20 disposed in the periphery of the pixel array section 10. The solid-state image sensing apparatus 1 has the pixel array section 10 adapted to color image sensing by a configuration in which, for example, color separation filters having R, G and B color filters are arranged in a 2×2 Bayer array for each of the unit pixels 3 in the pixel array section 10.

Though not shown in the drawing, the unit pixel 3 has a 4TR configuration in which a pixel signal generating section is composed of a readout selection transistor, a resetting transistor, a vertical selection transistor, and an amplifying transistor, in addition to a charge generating section for generating a signal charge upon detecting light. The pixel signal generating section may have a 3TR configuration obtained by omitting the vertical selection transistor from the 4TR configuration.

Though not shown in the drawing, the peripheral circuit section 20 includes an AD converting unit operable to perform a CDS (correlated double sampling) process and a digital conversion process, a vertical scanning unit operable to control a readout position in a vertical direction, a horizontal scanning unit operable to control a readout position in a horizontal direction, an output unit, a drive control unit operable to control the whole structure, and so on.

### First Application Example

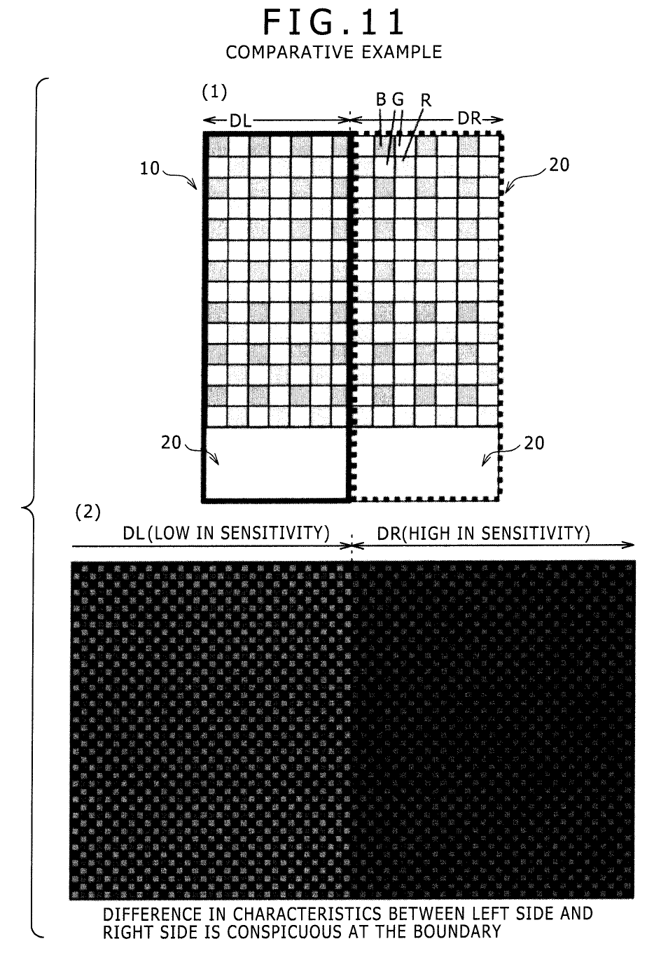

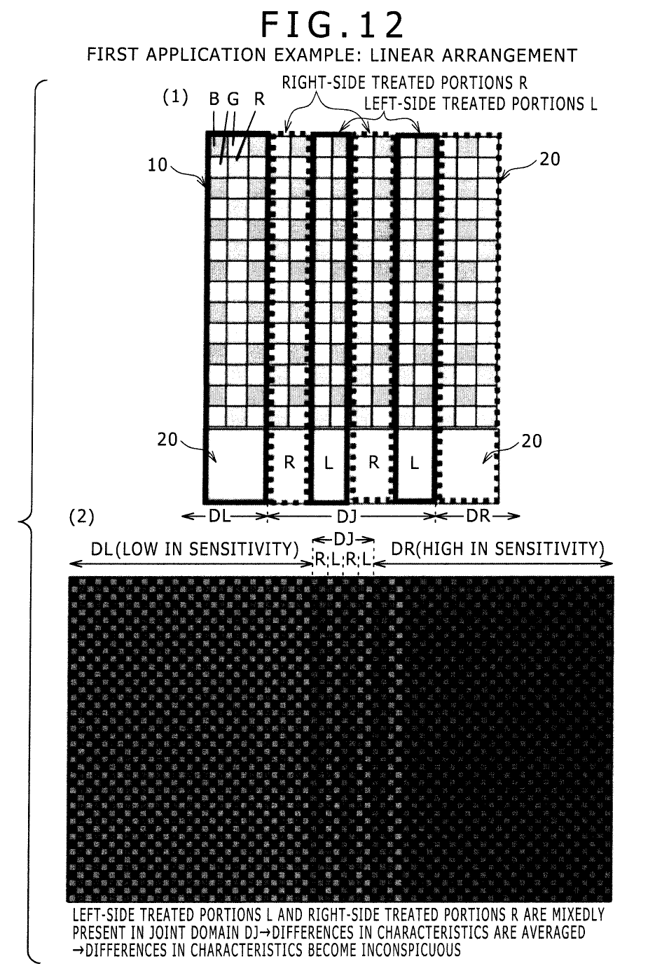

FIG. 11 and FIG. 12 show diagrams for illustrating a first application example. Paying attention to a central lower part of FIG. 10, FIG. 11 shows the relevant area of a comparative example in an enlarged form, and FIG. 12 shows the relevant area of the first application example in an enlarged form.

In the region dividing and joining method (two-time treatment) according to the comparative example, exposure in a right-side treatment and exposure in a left-side treatment are carried out clearly divisionally, with a central portion of the object area as a boundary, as shown in FIG. 11. In other words, the exposure area is divided by a certain continuous area. In this instance, as shown in FIG. 11(1), not only the pixel array section 10 but also the peripheral circuit section 20 is subjected to exposure divisionally on the left side and the right side by application of the region dividing and joining method.

It is assumed, for example, that signals outputted through the unit pixels 3 and the signal processing unit of the peripheral circuit section 20 formed by exposure in the left-side treatment are low in sensitivity and that signals outputted through the unit pixels 3 and the signal processing unit of the peripheral circuit section 20 formed by exposure in the right-side treatment are high in sensitivity. In this case, as shown in FIG. 11(2), a difference in characteristics (a difference in luminance reproduction performance or color reproduction performance) between the left side and the right side is conspicuously observed at the boundary between the left and right sides (at a central portion of the pixel array section 10).

On the other hand, in the region dividing and joining method (two-time treatment) according to the present embodiment, exposure areas relevant to the left-side treatment and exposure areas relevant to the right-side treatment are mixedly present in the joint domain DJ. In this example, the color separation filters in the Bayer pattern are arranged in the pixel array section 10 to adapt the latter to color image sensing, so that the pattern of the color separation filters is repeated every two pixels.

In view of the foregoing, in the joint domain DJ, the left-side treated portions L and the right-side treated portions R and the compositely treated portions LR are arranged in a corresponding manner, with a set of adjacent two unit pixels 3 as a unit. In addition, the exposure areas relevant to the left-side treatment and the exposure areas relevant to the right-side treatment are mixedly laid out at intervals of at least one set (two pixels). For instance, a layout in which the left-side treated portions L and the right-side treated portions R are respectively laid out every two pixels is applied. Incidentally, the compositely treated portions LR may be arranged. In this case, the compositely treated portions LR of the same layout mode may be arranged over the whole domain; or, alternatively, the compositely treated portions LR differing in layout mode may respectively be arranged at intervals of two pixels. Where the array of the color separation filters in the transverse (horizontal) direction is repeated every N pixels, it suffices to replace the expression “every two pixels” in the above description as to the Bayer array by the expression “every N pixels.” In any case, the exposure areas relevant to the left-side treatment and the exposure areas relevant to the right-side treatment are mixedly arranged, for every set of the color separation filters. This is based on the fact that the color reproduction performance is determined by the repeating unit of the array of the color separation filters.

The first application example differs from the other application examples described later, and is characterized, by a layout such that the layout mode of the exposure areas in the left-side treatment and the exposure areas in the right-side treatment are the same in the transverse (horizontal) direction. Specifically, paying attention to the transverse direction in regard of the joint domain DJ (the width direction of the joint domain DJ), the exposure areas relevant to the left-side treatment and the exposure areas relevant to the right-side treatment are arranged at the same pitch (in a distribution ratio of 1:1). In addition, paying attention to the longitudinal direction in regard of the joint domain DJ (the direction in which the joint domain DJ extends), the left-side treated portions L as the exposure areas in the left-side treatment and the right-side treated portions R as the exposure areas in the right-side treatment are respectively arranged in one row.

For instance, as shown in FIG. 12, the joint domain DJ is subjected to exposure divisionally by the right-side treatment (in the areas surrounded by broken-line frames in the figure) and the left-side treatment (in the areas surrounded by solid-line frames in the figure), with two pixels in the transverse direction (a green-blue combination and a green-red combination in the longitudinal direction) as a unit. More specifically, a right-side treated portion R, a left-side treated portion L, a right-side treated portion R, and a left-side treated portion L are arranged in this order from the left side toward the right side in the joint domain DJ. Though not shown in the figure, for example, an arrangement obtained by replacing the right-side treated portion R with a compositely treated portion R·L and replacing the left-side treated portion L with a compositely treated portion L·R, that is, an arrangement composed of the compositely treated portion R·L, the compositely treated portion L·R, the compositely treated portion R·L, and the compositely treated portion L·R in this order from the left side toward the right side may also be adopted. In this instance, as shown in FIG. 12(1), not only the pixel array section 10 but also the peripheral circuit section 20 is subjected to exposure divisionally on the left side and the right side.

As shown in FIG. 12(2), with the exposure areas in the left-side treatment and the exposure areas in the right-side treatment being mixedly present in the joint domain DJ, differences in sensitivity are averaged. Consequently, the contrast at the boundary can be shaded (gradated), differences in color reproduction performance can be moderated, and differences in characteristics at the central portion can be made inconspicuous.

According to the region dividing and joining method in the comparative example, the differences in characteristics at the central portion are conspicuous. On the contrary, according to the region dividing and joining method in the present embodiment, contrast and color vary gradually, whereby the differences in characteristics between the left side and the right side can be made inconspicuous.

While the exposure areas by the left-side treatment and the exposure areas by the right-side treatment are mixedly arranged every two pixels, corresponding to one set of the color separation filters, in the joint domain DJ in this example, the one set of color separation filters (two pixels) is not limitative of the unit for the mixed presence, and it suffices to adopt the set of the color separation filters (two pixels) as a unit. Though omitted in drawing, the exposure areas by the left-side treatment and the exposure areas by the right-side treatment may be mixedly arranged in the joint domain DJ every one integer times of two pixels, for example, every two sets (four pixels) or every three sets (six pixels).

### Second Application Example

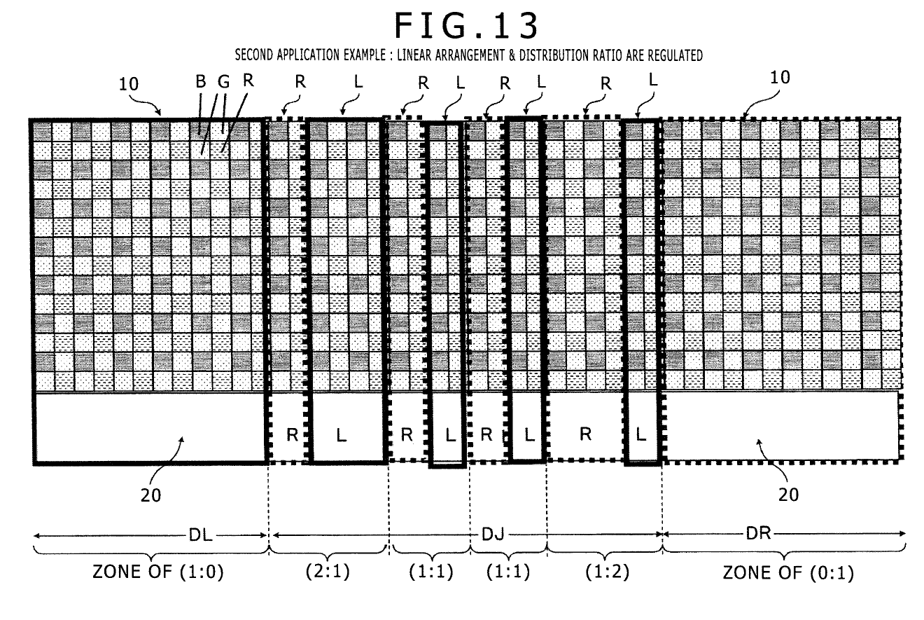

FIG. 13 illustrates a second application example. Here, also, a central lower part of FIG. 10 is paid attention to and is shown in an enlarged form.

The basic thought here is the same as that in the first application example above. The second application example, however, is characterized in that in the transverse direction, the array pitch (distribution ratio) of the exposure areas in the left-side treatment is different from that of the exposure areas in the right-side treatment. Specifically, at horizontal positions relative to (distances from) a central portion, the proportions of the array pitches of the exposure areas in the left-side treatment and the exposure area in the right-side treatment are varied so as to produce gradation. A configuration may be adopted in which the left-side treated portions L and the right-side treated portions R as above-mentioned are replaced with compositely treated portions LR and in which the distribution ratio of a device portion formed by the left-side treatment to a device portion formed by the right-side treatment, in each compositely treated portions LR, is regulated. Paying attention to the longitudinal direction of the joint domain DJ, the exposure areas in the left-side treatment and the exposure areas in the right-side treatment are respectively arranged in one row, like in the first application example. Besides, not only a pixel array section 10 but also a peripheral circuit section 20 is subjected to exposure divisionally on the left side and the right side by application of the region dividing and joining method, like in the first application example.

For example, the proportion of the exposure area relevant to the left-side treatment is represented as “a,” the proportion of the exposure area relevant to the right-side treatment is represented as “b,” and the distribution ratio of the exposure area by the left-side treatment to the exposure area by the right-side treatment is represented as “(a:b).” In the left-side domain DL and in the right-side domain DR, the proportion of the other kind of exposure area is zero (0).

In the example shown in FIG. 13, the layout of exposure areas is represented as

(1:0) . . . (1:0)(2:1)(1:1)(1:1)(1:2)(0:1) . . . (0:1). Thus, the distribution ratio is set at (1:1) in the vicinity of the boundary, and the distribution ratio is varied continuously (stepwise) according to the position relative to (distance from) the boundary so that the distribution ratio increases with the distance from the boundary. The expression “the distribution ratio increases” means that the averaged device characteristics of a pair of the two kinds of exposure areas are closer to the characteristics of the exposure areas in the left-side domain DL as the pair is located more to the left side, and are closer to characteristics of the exposure areas in the right-side domain DR as the pair is located more to the right side. Here, (1:0) . . . (1:0) denotes a portion in the left-side domain DL, (2:1)(1:1) denotes a portion in the left-side joint domain DJL, (1:1)(1:2) denotes a portion in the right-side joint domain DJR, and (0:1) . . . (0:1) denotes a portion in the right-side domain DR.

In the example shown in FIG. 13, a layout is adopted such that the distribution ratio of the exposure area by the left-side treatment to the exposure area by the right-side treatment is varied according to the position relative to (distance from) the boundary so that the distribution ratio increases with the distance from the central portion, but this layout is not indispensable to the present invention. In the joint domain DJ, the distribution ratio of the exposure area in the left-side treatment to the exposure area in the right-side treatment may not necessarily be continuously varied, insofar as the distribution ratio is varied. It should be noted here, however, that when the distribution ratio in the boundary region is set at (1:1) and the distribution ratio is varied continuously (stepwise) so that the distribution ratio at a position is higher as the position is farther from the boundary and nearer to the periphery, the averaged device characteristics of the pairs are varied smoothly, which naturally is considered to be favorable.

Though omitted in drawing, the distribution ratio may not necessarily be varied continuously, and may be varied in the manner of

(1:0) . . . (1:0)(2:1)(1:1)(1:2)(0:1) . . . (0:1). In addition, the same distribution ratio may be arranged successively, in such a manner as
(1:0) . . . (1:0)(2:1)(2:1)(2:1)(1:1)(1:1)(1:1)(1:2)(1:2)(1:2)(0:1) . . . (0:1).

In any case, in the joint domain DJ, the distribution ratio of the exposure area by the left-side treatment to the exposure area by the right-side treatment is set at a value other than (1:1), according to the position relative to (distance from) the central portion, whereby gradation is obtained. This results in a merit that the differences in characteristics can be made more inconspicuous.

### Third Application Example

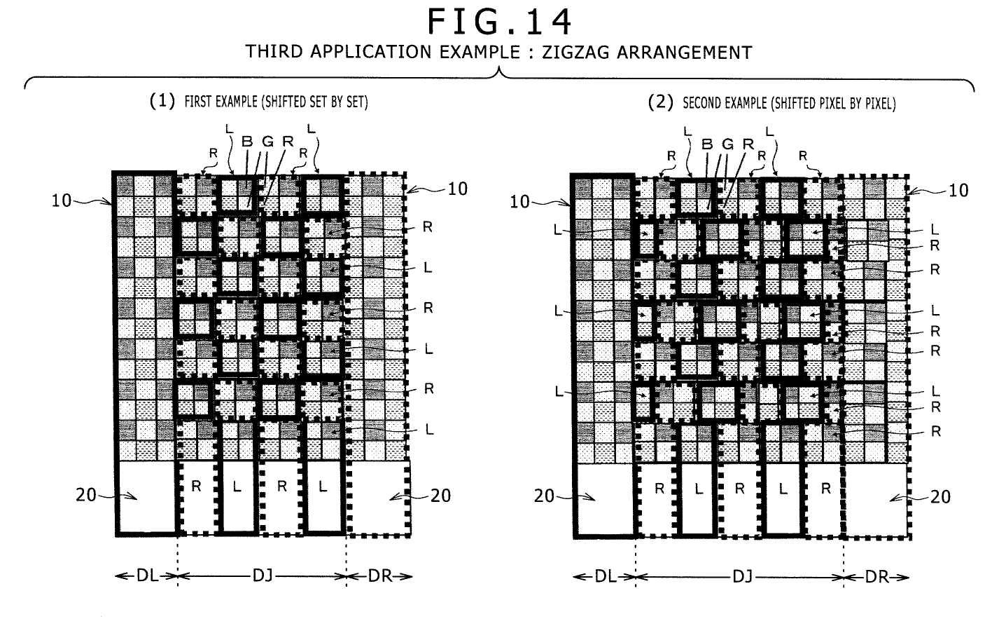

FIG. 14 illustrates a third application example. Here, also, a central lower part of FIG. 10 is paid attention to, and is shown in an enlarged form.

The basic thought here is the same as that in the first application example. The third application example, however, is characterized by a layout such that in the transverse (horizontal) direction, the layout mode of exposure areas by a left-side treatment and exposure areas by a right-side treatment differs line by line. Specifically, paying attention to the longitudinal direction of a joint domain DJ, the exposure areas by the left-side treatment and the exposure areas by the right-side treatment are respectively arranged zigzag (are not respectively arranged in a row).

In a first example shown in FIG. 14(1), the layout modes of the exposure areas by the left-side treatment and the exposure areas by the right-side treatment are interchanged every two pixels, corresponding to one set of the color separation filters. Paying attention to the longitudinal direction of the joint domain DJ, the exposure areas by the left-side treatment and the exposure areas by the right-side treatment are respectively arranged zigzag at a pitch of one set (two pixels). Specifically, in this layout, in the joint domain DJ, the left-side treated portions L and the right-side treated portions R in two-pixel units in size are respectively arranged zigzag at a pitch of one set (two pixels) (in a matrix with one set as a unit).

In a second example shown in FIG. 14(2), the layout modes of the exposure areas by the left-side treatment and the exposure areas by the right-side treatment are interchanged every one pixel. In this layout, in the joint domain DJ, the left-side treated portions L (compositely treated portions L·R) and the right-side treated portions R (compositely treated portions R·L) in two-pixel units in size are respectively arranged zigzag at a pitch of one pixel (in a matrix with half a set as a unit).

In any of these layouts, the exposure areas by the left-side treatment and the exposure areas by the right-side treatment are respectively arranged zigzag, producing a merit that differences in characteristics can be made inconspicuous, in the longitudinal (vertical) direction as well. Though not shown in the drawing, the right-side treated portions R and the left-side treated portions L may be replaced respectively by compositely treated portions R·L and compositely treated portions L·R, which may respectively be arranged zigzag.

In the case of adopting the zigzag arrangement, a variety of modifications are possible, though omitted in drawing. In the transverse direction, this arrangement may be combined with the layout in which the exposure areas by one treatment and the exposure areas by another treatment are mixedly arranged in the joint domain DJ at intervals of one integer times of two pixels, like in the first example. In the longitudinal direction, also, the layout of the exposure areas is not limited to the zigzag arrangement having a pitch of one set (two pixels) or one pixel, and may be a zigzag arrangement having a pitch of an arbitrary number of pixels or of sets. Besides, the pitch (ratio, shift amount) may not necessarily be kept constant in the longitudinal direction (the exposure areas may not necessarily be arranged in the same ratio continuously in the longitudinal direction), and the pitch of the zigzag arrangement may differ line by line. In this case, the layout mode of the exposure areas by the left-side treatment and the exposure areas by the right-side treatment is made more random, which is advantageous in that differences in characteristics can be made more inconspicuous.

### Fourth Application Example

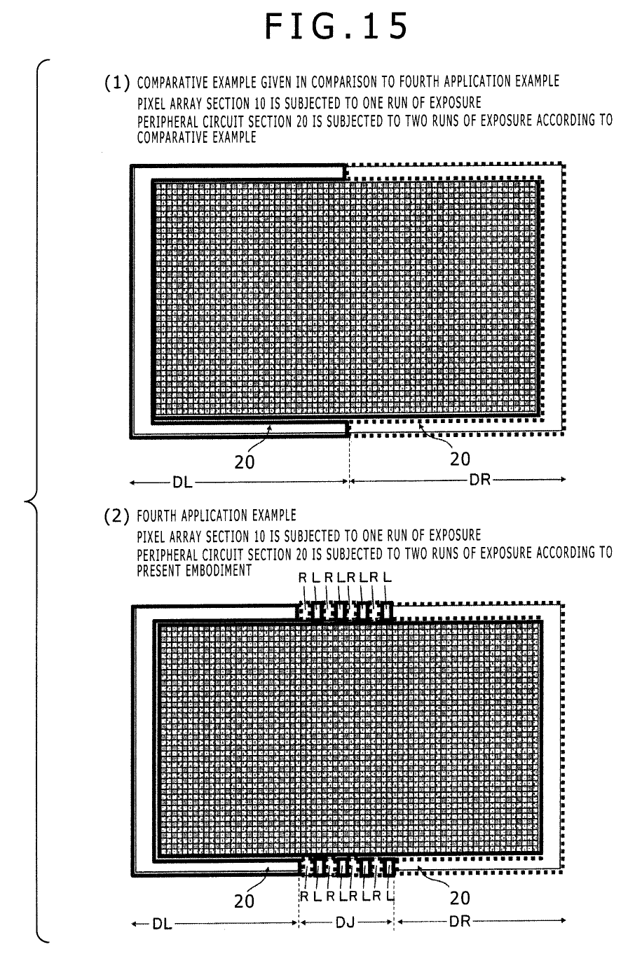

FIG. 15 illustrates a fourth application example.

In the first to third application examples above, the region dividing and joining method has been applied not only to the pixel array section 10 but also to the peripheral circuit section 20. In the fourth application example, on the other hand, the region dividing and joining method is not applied to the pixel array section 10 but is applied only to the peripheral circuit section 20.

The demand for application of the region dividing and joining method resides in that fine devices should be formed over a large area which exceeds the size suitable for one-shot formation. Therefore, even in the case where the solid-state image sensing apparatus 1 as a whole inclusive of the peripheral circuit section 20 has a large area in excess of the size suitable for one-shot process, if the size of the pixel array section 10 is within the size suitable for one-shot formation, it is preferable to form the pixel array section 10 by a one-shot process without applying the region dividing and joining method. The fourth application example is an example of application to such a situation.

Only the pixel array section 10 is formed by one shot without applying the region dividing and joining method, and the peripheral circuit section 20 is formed by applying the region dividing and joining method. In this case, it may be contemplated to apply the region dividing and joining method of the comparative example to the peripheral circuit section 20, as shown in FIG. 15(1). In this case, however, there remains the problem that the differences in characteristics arising from devices in the boundary regions constituting the peripheral circuit section 20 will be conspicuously observed.

In view of this, in the fourth application example, only the pixel array section 10 is formed by one run of exposure without applying the region dividing and joining method, and the peripheral circuit section 20 is formed by applying the region dividing and joining method according to the present embodiment. Since the pixel array section 10 is formed without applying the region dividing and joining method, the make of the pixel array section 10 (unit pixels 3) can be uniform. As for the peripheral circuit section 20, the application of the region dividing and joining method according to the present embodiment ensures that the exposure areas by the left-side treatment and the exposure areas by the right-side treatment are mixedly present in the joint domains DJ in the peripheral circuit section 20. Consequently, the differences in characteristics arising from devices in the boundary regions constituting the peripheral circuit section 20 can be made inconspicuous, as compared to the case where the region dividing and joining method according to the comparative example is applied.

### Fifth Application Example

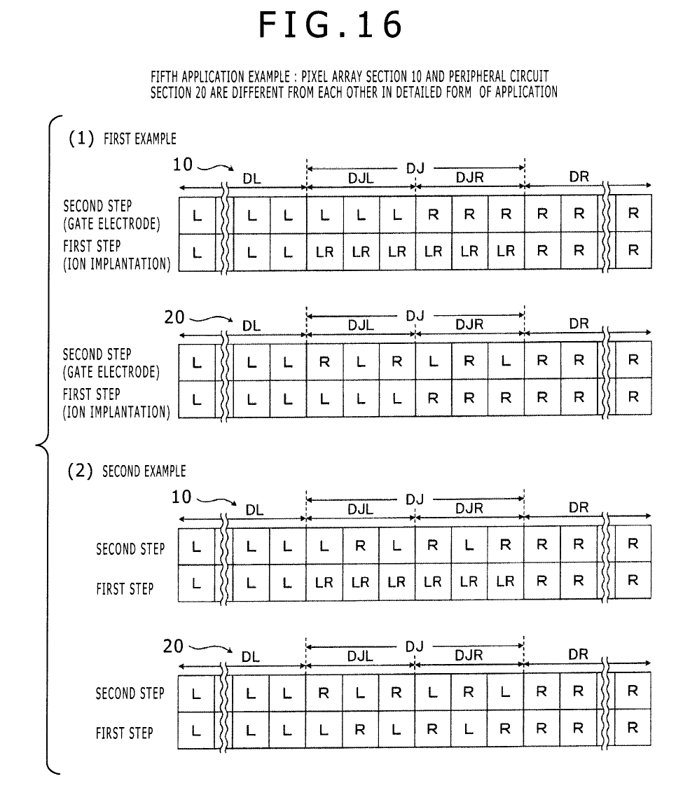

FIG. 16 illustrates a fifth application example.

The fifth application example is characterized in that both a pixel array section 10 and a peripheral circuit section 20 are formed by applying the region dividing and joining method according to the present embodiment but that the detailed form of application of the method is different between the pixel array section 10 and the peripheral circuit section 20.

In an example of “the detailed form of application,” there is set a difference between the pixel array section 10 and the peripheral circuit section 20 in the object steps to which the region dividing and joining method according to the present embodiment is applied (first example). This first example is illustrated in FIG. 16(1). As to the pixel array section 10, a layout in which only compositely treated portions LR formed by application of the present embodiment are provided in a first step (ion implantation step) shown on the lower side, and a condition obtained without application of the present embodiment is provided in a second step (gate electrode forming step) shown on the upper side. As for the peripheral circuit section 20, the present embodiment is not applied in a first step (ion implantation step) shown on the lower side, and a condition where only left-side treated portions L and right-side treated portions R are alternately arranged is provided in a second step (gate electrode forming step) shown on the upper side.

In another example of “the detailed form of application,” there is set a difference between the pixel array section 10 and the peripheral circuit section 20 in the combination of layout modes of device characteristics used in applying the region dividing and joining method of the present embodiment to a plurality of steps (layers) (second example). This second example is illustrated in FIG. 16(2). As to the pixel array section 10, a condition where only compositely treated portions LR are arranged is provided in a first step shown on the lower side, and a condition where only left-side treated portions L and right-side treated portions R are alternately arranged is provided in a second step shown on the upper side. As for the peripheral circuit section 20, a condition where only left-side treated portions L and right-side treated portions R are alternately arranged is provided in a first step shown on the lower side, a condition where only the left-side treated portions L and the right-side treated portions R are alternately arranged is provided in a second step shown on the upper side, and the layout of the left-side treated portions L and the right-side treated portions R in the first step and that in the second step are in an alternate relation with each other.

Incidentally, the combinations as to the detailed forms illustrated here are mere examples, and various modifications are possible. A variety of combination modes can be adopted, depending on whether or not the region dividing and joining method according to the present embodiment is applied, and on the detailed form of application if the method is applied, in each of the steps for forming each of the regions (here, the pixel array section 10 and the peripheral circuit section 20). In that case, not only the first and second examples of the basic manufacturing method illustrated in FIG. 3(1) and FIG. 3(2) but also the above-described first to third application examples (linear arrangement, regulation of distribution ratio, and zigzag arrangement) can be combined in arbitrary manners. The combination of a plurality of steps determines the final device characteristics in the joint domain DJ, which is advantageous in that the manner of mixing of device characteristics can be controlled more easily.

The present application contains subject matter related to that disclosed in Japanese Priority Patent Application JP 2008-315468 filed in the Japan Patent Office on Dec. 11, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor apparatus, wherein
a technique for manufacturing one semiconductor region by dividing the one semiconductor region into a plurality of divisional regions in regard of a step is applied, and
one-side device portions formed simultaneously by a one-side treatment conducted primarily for the divisional region on one side and other-side device portions formed simultaneously by an other-side treatment conducted primarily for the divisional region on the other side are mixedly present in a joint region joining a boundary between the divisional regions.

2. The semiconductor apparatus according to claim 1, wherein
the one-side device portion and the other-side device portion correspond respectively to specific portions of each device, and the one-side device portions and the other-side device portions are alternately arranged.

3. The semiconductor apparatus according to claim 1, wherein
a specific portion of each device is composed of composition of the one-side device portion and the other-side device portion.

4. The semiconductor apparatus according to claim 3, wherein
the size, in a width direction of the joint region, of the specific portion of each device composed of composition of the one-side device portion and the other-side device portion is different from the size or sizes, in the width direction of the joint region, of the specific portion of each device in other regions than the joint region which are formed respectively by the one-side treatment and the other-side treatment.

5. The semiconductor apparatus according to claim 3, wherein
a region is present in which the one-side device portion and the other-side device portion overlap each other in a specific portion of each device.

6. The semiconductor apparatus according to claim 1, wherein
the one-side device portions and the other-side device portions are respectively arranged in a row in a direction in which the joint region extends.

7. The semiconductor apparatus according to claim 1, wherein
the one-side device portions and the other-side device portions are respectively arranged in a zigzag pattern in a direction in which the joint region extends.

8. The semiconductor apparatus according to claim 7, wherein
the one-side device portions, the other-side device portions, or composite portions each composed of the one-side device portion and the other-side device portion are arranged in a corresponding manner, with a set of a plurality of adjacent devices as a unit, and
the device portions or composite portions are respectively arranged in the zigzag pattern at a pitch of the set.

9. The semiconductor apparatus according to claim 7, wherein
the one-side device portions, the other-side device portions, or composite portions each composed of the one-side device portion and the other-side device portion are arranged in a corresponding manner, with a set of a plurality of adjacent devices as a unit, and
the device portions or composite portions are respectively arranged in the zigzag pattern at a pitch of each device.

10. The semiconductor apparatus according to claim 1, wherein
a plurality of pairs of the one-side device portion and the other-side device portion are arranged in the width direction of the joint region, and the distribution ratio between the one-side device portion and the other-side device portion in each of the pairs varies depending on the position of the relevant pair relative to the boundary.

11. The semiconductor apparatus according to claim 10, wherein
the distribution ratio at the boundary is (1:1), and the distribution ratio increases with the distance from the boundary.

12. The semiconductor apparatus according to claim 1, wherein
the one semiconductor region includes a main circuit section disposed on the inner side and a peripheral circuit section disposed in the periphery of the main circuit section,
the main circuit section is formed without applying the technique for manufacturing one semiconductor region by dividing the one semiconductor region into a plurality of divisional regions, and
the peripheral circuit section is formed by applying the technique for manufacturing one semiconductor region by dividing the one semiconductor region into a plurality of divisional regions, with one-side device portions and the other-side device portions being mixedly present in a joint region joining a boundary between the divisional regions.

13. A method of manufacturing a semiconductor apparatus, comprising
manufacturing one semiconductor region by dividing the one semiconductor region into a plurality of divisional regions in regard of a step, wherein
in a one-side treatment conducted primarily for the divisional region on one side, one-side device portions are formed in the one-side divisional region, and at least part of the one-side device portions are formed also in a joint region near a boundary between the divisional regions, and
in an other-side treatment conducted primarily for the divisional region on the other side, at least part of an other-side device portion is formed also in a space between the one-side device portions in the joint region.

14. The method of manufacturing the semiconductor apparatus according to claim 13, wherein
at least in an ion implantation step, a one-side mask used in the one-side treatment and an other-side mask used in the other-side treatment are different from each other in layout relation of opening portions and shield portions in the joint region.

15. The method of manufacturing the semiconductor apparatus according to claim 14, wherein
in forming a specific portion of each device respectively by the opening portion of the one-side mask and the opening portion of the other-side mask in the case where the device portions correspond to the opening portions of the masks,
the one-side mask is provided with the opening portions each at a portion corresponding to the whole of the one-side device portion, the remainder of the one-side mask being a shield portion, and
the other-side mask is provided with the opening portions each at a portion corresponding to the whole of the other-side device portion, the remainder of the other-side mask being a shield portion.

16. The method of manufacturing the semiconductor apparatus according to claim 14, wherein
in forming a specific portion of each device respectively by the shield portion of the one-side mask and the shield portion of the other-side mask in the case where the device portions correspond to the shield portions of the masks,
each of the one-side mask and the other-side mask is provided with the shield portions each at a portion corresponding to the whole of the one-side device portion and at a portion corresponding to the whole of the other-side device portion, the remainder of each of the one-side mask and the other-side mask being an opening portion.

17. The method of manufacturing the semiconductor apparatus according to claim 14, wherein
in the case where a specific portion of each device is composed of composition of the one-side device portion and the other-side device portion,
an opening portion for use in forming one device is arranged divisionally in the one-side mask and the other-side mask, and
a light shield portion for use in forming the one device is arranged in both of the one-side mask and the other-side mask.

18. The method of manufacturing the semiconductor apparatus according to claim 17, wherein
in forming a specific portion of each device by composition of the opening portion of the one-side mask and the opening portion of the other-side mask in the case where the device portions correspond to the opening portions of the masks,
the one-side mask is provided with the opening portions in the whole of a portion corresponding to the one-side device portion and in at least part of a portion corresponding to the other-side device portion,
the other-side mask is provided with the opening portions in the whole of a portion corresponding to the other-side device portion and in at least part of a portion corresponding to the other-side device portion, and
the opening portions and the shield portions of the respective masks are so set that the opening portion of the one-side mask and the opening portion of the other-side mask overlap each other when there is no offset between the one-side mask and the other-side mask.

19. The method of manufacturing the semiconductor apparatus according to claim 17, wherein
in forming a specific portion of each device by composition of the shield portion of the one-side mask and the shield portion of the other-side mask in the case where the device portions correspond to the shield portions of the masks,
the one-side mask is provided with a shield portion which is wider than the whole of a portion corresponding to the specific portion of each device, and
the other-side mask is provided with a shield portion which is wider than the whole of a portion corresponding to the specific portion of each device.
